(19) United States
(12) Patent Application Publication
(10) Pub. No.: US 2012/0198591 A1
(43) Pub. Date: Aug. 2, 2012

(54) ROOM TEMPERATURE QUANTUM FIELD EFFECT TRANSISTOR COMPRISING A 2-DIMENSIONAL QUANTUM WIRE ARRAY BASED ON IDEALLY CONDUCTING MOLECULES

(76) Inventor: Frank Michael Ohnesorge, Erlangen (DE)

(21) Appl. No.: 13/395,078

(22) PCT Filed: Sep. 13, 2010
(86) PCT No.: PCT/IB10/54110

§ 371 Date: Mar. 8, 2012

(30) Foreign Application Priority Data
Sep. 17, 2009 (DE) DE102009041642.0
May 17, 2010 (GB) 1008164.4
Jul. 26, 2010 (GB) 1012497.2

(51) Int. Cl. G01Q 60/04; H01L 29/66

(52) U.S. Cl. 850/23; 257/9; 257/E29.168

(57) ABSTRACT

One, several or very many parallel quantum wires, e.g. especially 1-dimensional quantum-conducting heavy ion tracks—“true” quantum wires at room temperature—see similarly EP1096569A1 [1] and [2], or also perhaps SWCNTs, vertically directed or also slightly tilted—up to about 45 degrees—arranged in a 2 dimensional plane, which as a 2-dimensional array interconnect the source and drain contacts of the here invented transistor, are modulated with respect to their quantum-mechanical conductivity via the strength of an applied electric or magnetic field [3], which is homogenous or variable in space locally across the 2 dimensional quantum wire array. The I-V curves of such quantum wires are measured via a double resonant tunnelling effect which allows identifying quantum effects at room temperature. A “true” quantum wire is characterized by quantized current steps and sharp current peaks in the I-V (Isd versus Usd, not just Is a versus Ugate) curve. In the ideal case the quantum wires consist of straight polyacetylene-reminiscent molecules of the cumulene form ( . . . ═C═C═C═C═C═C═ . . . ) or of the form ( . . . —C≡C—C≡C—C≡C— . . . ) which are generated by the energy deposition during the single swift (heavy) ions' passage through the insulating DLC-layer. The switching time of the transistor is determined practically solely by the switching time of the magnetic field (time constant of the “magnetic gate”), the ohmic resistance of the source-drain connection via the quantum wire array is in the conducting state practically zero. The controlling “gate”-magnetic field having a component normal to the quantum wires can be generated by a small controlling current through some inductance (embodiment 1, FIG. 7, 8, 9, 10, 11) or also by a suitable (locally variable) direction of the magnetization in a ferromagnetic thin layer (e.g. Fe, Co, Ni, etc.)—embodiment 2, FIG. 8, 9, 10, 11—, or also for example in a thin layer consisting of metallic (ferromagnetic) nanoparticles (e.g. Fe, Co, Ni, etc.) or also “current-less” through an electrostatically charged tip (embodiment 3a analogous to FIG. 7) or via a suitable polarization of a ferroelectric thin layer or liquid crystals/nanoparticles in an electric field—embodiment 3b, as in FIG. 8, 9, 10, 11. The quantum wire transistor can also be switched/controlled optically. Applications in the case of very large arrays (>1010/cm2 parallel QWs) would be a power transistor, in the case of very small arrays (single or a few parallel QWs) it would be non-volatile information storage, where due to the particular properties of 1-dimensional quantized conductivity a multi-level logic can be realized. In the case of optical switching/controlling of the quantum wire transistor, an extremely highly resolving 2-dimensional array of photodetectors is envisionable, where in that case the single QWs would have to be electrically connected one by one, e.g. reminiscent of the concept of a Nand- or Nor-Flash-Ram, whose size scale in turn is supposedly determining the limit of the achievable area density of the pixels. A feasible concept for a read-out matrix for possible applications of these quantum field effect transistors as a non-volatile memory chip or as a ultrahighly resolving light pixel detector array is reminiscent of the concept of a Nor-Flash-Ram. The concept is comprising a crossed comb structure of nanometric electrically conducting conventional leads on either side of the DLC-layer embedding the vertical quantum wires as shown in FIG. 23 each crossing on average being interconnected by one or a few ion track quantum wires. A feasible concept for a wiring matrix writing onto the quantum field effect transistors for a non-volatile memory chip is shown in FIG. 11 comprising a meander-shaped circuitry.

### SUMMARY

One, several or very many parallel quantum wires, e.g. especially 1-dimensional quantum-conducting heavy ion tracks—“true” quantum wires at room temperature—see similarly EP1096569A1 [1] and [2], or also perhaps SWCNTs, vertically directed or also slightly tilted—up to about 45 degrees—arranged in a 2 dimensional plane, which as a 2-dimensional array interconnect the source and drain contacts of the here invented transistor, are modulated with respect to their quantum-mechanical conductivity via the strength of an applied electric or magnetic field [3], which is homogenous or variable in space locally across the 2-dimensional quantum wire array. The I-V curves of such quantum wires are measured via a double resonant tunnelling effect which allows identifying quantum effects at room temperature. A “true” quantum wire is characterized by quantized current steps and sharp current peaks in the I-V (I_{sd} versus U_{sd}, not just I_{sd} versus U_{gate}) curve. In the ideal case the quantum wires consist of straight polyacetylene-like molecules of the cumulene form ( . . . ═C═C═C═C═C═C═ . . . ) or of the mesomeric form ( . . . —C≡C—C≡C—C≡C— . . . ) which are generated by the energy deposition during the single swift heavy ions' passage through the insulating DLC-layer.

The switching time of the transistor is determined practically solely by the switching time of the magnetic field (time constant of the “magnetic gate”), the ohmic resistance of the source drain connection via the quantum wire array is in the conducting state practically zero. The controlling “Gate”-magnetic field having a component normal to the quantum wires can be generated by a small controlling current through some inductance (embodiment 1, FIGS. 7, 8, 9, 10, 11) or also by a suitable (locally variable) direction of the magnetization in a ferromagnetic thin layer (e.g. Fe, Co, Ni, etc.)—embodiment 2, FIGS. 8, 9, 10, 11—, or also for example in a thin layer consisting of metallic (ferromagnetic) nanoparticles (e.g. Fe, Co, Ni, etc.) or also “current-less” through an electrostatically charged tip (embodiment 3a analogous to FIG. 7) or via a suitable polarization of a ferroelectric thin layer or liquid crystals/nanoparticles in an electric field—embodiment 3b, as in FIG. 8, 9, 10, 11. The quantum wire transistor can also be switched/controlled optically. Applications in the case of very large arrays (>10¹⁰/cm² parallel QWs) would be a power transistor, in the case of very small arrays (single or a few parallel QWs) it would be non-volatile information storage, where due to the particular properties of 1-dimensional quantized conductivity a multi-level logic can be realized. In the case of optical switching/controlling of the quantum wire transistor, an extremely highly resolving 2-dimensional array of photodetectors is thinkable/imaginable/envisionable, where in that case the single QWs would have to be electrically connected one by one, reminiscent of the concept of a Nand- or Nor-Flash-Ram, whose size scale in turn is supposedly determining the limit of the achievable area density of the pixels.

A feasible concept for a read-out matrix for possible applications of these quantum field effect transistors as a non-volatile memory chip or as a ultrahighly resolving light pixel detector array is reminiscent of the read-out concept of a Nor-Flash-Ram. The concept is comprising two crossed comb structures of nanometric electrically conducting conventional leads on either side of the DLC-layer embedding the vertical quantum wires as shown in FIG. 23 each crossing on average being interconnected by one or a few ion track quantum wires. A feasible concept for a wiring matrix for writing onto the quantum field effect transistors for a non-volatile memory chip is shown in FIG. 11 comprising a meander-shaped circuitry either also designed using the said quantum wire array of the present invention or alternatively using conventional vertical wires. For both concepts, it is also possible to adjust the design such that small groups/entities of several parallel quantum wires are addressed by one single lead connection.

### Introduction:

The measurement set-up (FIG. 1) for measuring the characteristic source-drain current versus source-drain voltage I_{sd}-U_{sd} curves of single “true” quantum wires at room temperature mainly consists of a combined scanning force and scanning tunnelling microscope (AFM/STM), where the electrically conductive probe tip at the end of a cantilever spring is initially scanned line by line across the vertical quantum wire array (FIG. 15). Then the scanning is stopped right above the terminus of one quantum wire and the quantum wire's I-V curve is measured across a protective resistor (minimum 25.8 kΩ or minimum 6.45 MΩ respectively), while the probe tip is in contact with the one end of the quantum wire defined as the source-contact. The quantum wires' opposite (lower end) terminations, i.e. the entity of the drain contacts are mainly via a protective resistor (minimum 25.8 kΩ or minimum 6.45 MΩ respectively) and an I-V-converter connected to earth ground.

The characteristic I-V curves of a “true” quantum wire are characterized on one hand by a non-linear staircase curve (FIG. 3) I_{sd} versus U_{sd} on a 100 mV to 1V scale and characterized on the other hand by a flat I-V-curve within the plateaus, especially the zero-level (current suppression level) around 0 Volts+/−100 mV with extremely sharp current peaks (FIG. 5) at equal separations of about 2 mV. The stair case I-V curve is a functional feature particularly of the charge quantization but also the conductance quantization, the sharp current peaks especially within the current suppression plateau are solely a functional feature of the conductivity/conductance quantization in a truly 1-dimensional quantum wire—both functional features are necessary to speak of a “true” quantum wire with 1-dimensional conductivity, the charge quantization alone is not sufficient. Upon applying a gate field the ideal 1-dimensional conductivity breaks down immediately in the single quantum wires, in the case of a B-field perpendicular to the quantum wires by strong scattering of the wave-like transmitted ballistic electrons at the quantum wire's “walls”, very much simplified viewable as a kind of Hall-effect in a 1-dimensional conductor. FIG. 4 shows the staircase I-V curve through a quantum wire strongly modulated by an external gate field. This is possible because the quantized 1-dimensional conductivity of a “true” quantum wire responds extremely sensitively to external fields, especially quasi-static electromagnetic fields and breaks down completely in a single quantum wire at the smallest applied external fields. The mere Coulomb charging blockade's I_{sd}-V_{sd}-curve would not be affected by external fields in this particular way, mere charge quantization would only account for a staircase I_{sd} (current) versus a gate field strength (e.g. U_{gate}, gate voltage, i.e. E-field or also B-field strength) curve. The functional feature of conductance quantization in the I_{sd}-U_{sd} curve is made possible by the extremely perturbation-free geometrical 1-dimensionality of the here employed ion track quantum wires, which are light ray straight and exhibit a minute diameter of order 1 nm and smaller. In the ideal case they consist of single walled carbon nanotubes (SWCNTs) or of “graphitized” chains of carbon double bonds of the cumulene form ( . . . ═C═C═C═C═C═C═ . . . ) or of the mesomeric form of poly-acetylene-reminiscent molecules ( . . . —C≡C—C≡C—C≡C— . . . ). In the case of an applied B-field the perturbation of the 1-dimensional conductivity can be regarded as a kind of Hall effect in the quantum wire, where the ideal conductivity immediately breaks down in the single quantum wires because of scattering of the ballistic electrons in the quantum wire with its boundaries. Alternatively the 1-dimensional conductivity/conductance can here be viewed as transmission through the highest (partly) occupied or lowest (partly) unoccupied molecular orbital (HOMO/LUMO) of a straight polymeric carbon chain which as well breaks down if this over the whole polymeric length extended HOMO/LUMO gets (strongly) perturbed by even a small applied external field and thus destroyed into smaller separate orbitals. The same holds if the straight quantum wire gets bent by any influence, e.g. like a phonon or acoustic perturbation.

The 1-dimensionally quantized electrical conductivity of the quantum wires here is indeed characterized in that, that the source-drain-current-voltage (I_{sd} plotted versus U_{sd}) curve at room temperature firstly (see FIG. 3) is a staircase characteristic (with steps/almost plateaus on an 0.2-0.5 Volts scale on the U_{sd}-axis) with at higher voltages occurring negative differential resistance (caused by Esaki-tunnelling of “hot electrons”), and that secondly (see FIG. 5) especially in an U_{sd}-range in the vicinity around 0 Volts, i.e. especially in the first Coulomb suppression plateau extremely sharp current (I_{sd}) peaks are occurring, caused by (quantum) peaks in the 1-dimensional conductance at source-drain voltages U_{sd} with a separation in voltage of about 2 mVolts. Needle-like current peaks (I_{sd}) of a height up to 1 nAmpere were observed significantly below source drain voltages of 50-200 mVolts. In particular, it is hereby emphasized, that the characteristic curves I_{sd} versus U_{sd} are measured and plotted, not—as usually—I_{sd} versus a gate voltage or a gate field strength respectively (e.g. B-field) was displayed. In the usual case of I_{sd} versus gate field a staircase characteristic is resulting due to sole charge quantization (Coulomb blockade), in the case of I_{sd} versus U_{sd} a staircase characteristic is resulting, but especially the quantized conductance (manifested in sharp peaks in the current I_{sd}) peaks are resulting not until actual 1-dimensional ballistic transmission conductivity—i.e. a tunnelling of the conducting electrons through the 1-dimensional quantum states just like in a wave guide—is in effect, and the lateral extension of the quantum wire is of the size order of the Fermi-wavelength (O(a few Angströms to 1 nanometer)) of the electrons, and not just the mean free path or phase coherence length (with respect to the diffusive scattering of the electron at atoms, other electrons, phonons), which are much larger and temperature-dependent. The theory about this is treated e.g. in [4].

The I-V characteristics can of course also be modulated by external gate fields, even at room temperature: These true quantum wires possess I-V curves, which are characterized by the fact that the source-drain I-V curves I_{sd} versus U_{sd} “along” such a “true” quantum wire can be modulated or controlled or switched very sensitively—since their conductivity is based on electron transmission through 1-dimensional quantum mechanical states—by applied external fields—magnetic/electric/electro-acoustic (FIG. 4) and optical (FIG. 13); in FIG. 4 it is emphasized how clearly and pronouncedly the stair case curve is enveloping the effect of the gate field modulation in time, where again the x-axis is merely actually representing the voltage U_{sd} and not a measure of the gate field. The periodic modulation of the I_{sd}-U_{sd}-curve is in fact caused by a periodically modulated gate field, mere Coulomb charge quantization would never show this behaviour of the I-V-curve (see also above). Mere Coulomb blockade effect would only account for a overall non-linear I_{sd}-U_{sd}-curve similar to FIGS. 6 and 17, a staircase curve would only be expected for the current I_{sd} as a function of a gate field strength (U_{gate}/E-field strength or B-field strength) at a constant source drain voltage U_{sd}. Especially if source and drain electrodes—which can be micro-structured—also show ballistic conductivity (see e.g. [5], for the case of Tu and Mo at very low temperatures), here perhaps if e.g. would be consisting of crystalline Cu or Au already at moderately low temperatures or if would be a superconductor at low temperatures or even would consist of a 2-dimensional electron gas—2-DEG—at room temperature and the 2-dimensional nano wire array would consist of very well identical quantum wires (geometry, material)—embodiment 5, FIG. 14—then phase-dependent (wave function of the ballistic electrons) effects in the quantum wires would enhance the sensitivity (i.e. the gain) of the transistor function significantly, since for instance an applied (inhomogeneous) B-field (-component) vertical to the quantum wires would instantaneously induce various phase shifts of the wave functions (free electron in the 1-dimensional electron gas, or an electron which is transmitted through a 1-dimensional quantum state, i.e. is tunnelling into and out of that quantum state) in all those many quantum wires and the resulting total summed up transmission current (summed as vectors/“interferometrically”) through all the wires—the entity of the wires—would be drastically reduced—in complete analogy to a quantum interference device, e.g. just like a SQUID. This effect would occur already, even though weaker, if the electrodes are not ideal metals nor even 2-DEGs/superconductors, at room temperature. A 2-DEG as source and drain electrode would of course also function at room temperature which would be the ideal case. The current through quantum wires can also be modulated optically (embodiment 4, FIG. 12) by roughly infrared light, since then excitations between quantum states in the quantum wires can occur. (z.B. [6]). This (FIG. 13) also shows experimentally, that using the present invention's set-up, current can even be generated just like in a solar cell (FIG. 13, current flow of several 0.1 nAmpere at voltages of 0 Volts through a single quantum wire under illumination, while the exact power contribution of that single quantum wire could not yet be evaluated because of the other two simultaneously illuminated and even on a large area illuminated hetero junctions (at the QW-terminations) of the experimental set-up, which alone without a quantum wire in between, however, neither are showing a pronounced plateau nor a non-zero current I_{sd} at U_{sd}=0 in the I_{sd}-U_{sd}-characteristics—as the I-V-characteristic “without quantum wire” visible in FIG. 6—and without the quantum wire are delivering a current higher by a factor of 1000 at the same voltage modulation/cycling—i.e. delivers a I_{sd}-U_{sd} characteristics a factor of 1000 steeper without any plateaus. At a counter (opposite) voltage of about 0.2 Volts, the current under illumination is suppressed to zero, which leads to an estimated (total) power of the single quantum wire photo cell of 0.02 nWatts.

If the QWs in the 2-dim array are electrically contacted one by one, i.e. if they can be “read out” one by one, because of the photo sensitivity of the QWs a extremely highly resolution-capable photodetector array can be realized (far more than one pixel per (100 nm)²). This electrical contact could be realized via a resistor or semiconductor junction cascade reminiscent of a shift register or a regular CCD-array or a Nand-/Nor-Flash-Ram—modern (and also elaborate) lithography methods allow such small structure sizes such as the simple concept proposed in FIG. 23. At such high area density of the pixels (up to about 10¹² per cm² would be feasible), it can be spoken of an artificial retina.

The primary, and most simply realizable embodiment of the here invented mesoscopic quantum-electronic component is a power transistor, in which the current through each of these approximately 10¹ parallel QWs/cm² is modulated or switched via a magnetic field, where the I_{sd}-U_{sd} characteristic resulting from the sum of all currents through the many single QWs of such a magnetic field effect power transistor can be tailored through adjustment of the spatial variation of this magnetic field across the 2 dimensional array of QWs. This can be realized for instance by a strong and variable B-field gradient emanating from a tip-shaped soft-iron-core (adjustable inhomogeneous B-field) or by a ferromagnetic film—e.g. deposited on the source electrode—whose magnetization can be “written” laterally (spatially) variable which in turn stores this spatially defined inhomogeneous magnetization in a non-volatile manner, even after the electro-magnetic “writing” tip has been removed. At a current of about 1 nAmpere per QW (at about 1 Volt applied source-drain-voltage U_{sd}) a total controlled current of 10 Amperes per cm² component surface area is basically possible. This power QFET is characterized by an extremely small blocking current, since the noise floor during the current measurement is <pA at 1 nA current along the quantum wire. The total source drain current I_{sd} can also be modulated optically (see above), similarly applicable like a photo-thyristor.

If all the parallel QWs are electrically contacted in small groups (only a few parallel or even single QWs), via the above mentioned “writing” magnetization a computer mass storage device can be realized—see patent claim 12.

One manufacturing method of such an array of very many parallel QWs, vertically embedded in an insulating film (e.g. DLC, SiC, polymers) for use in such an here invented power transistor is extensively described in [1], where the achievable maximum area density of such vertical parallel QWs while still being sufficiently electronically insulated from each other, is roughly 10¹¹ wires/cm². Since the latent particle tracks—(heavy) ion tracks—show clear electronic quantization effects at room temperature (staircase I-V-curve, sharp quantum conductance/current peaks, “along” the QWs i.e. in I_{sd} versus U_{sd}, not just I_{sd} versus U_{gate}), which means that they are “truly” room temperature QWs, it is supposed/suggested that the directed/oriented impact of single high energy ions (i.e. extremely high energy density) generates single SWCNTs or graphitized carbon chains of the form of polyacetylene-reminiscent molecules of the cumulene form . . . ═C═C═C═C═C═C═ . . . or of the mesomeric form ( . . . —C≡C—C≡C—C≡C— . . . ) by extremely local “graphitization” of the DLC material; this is because such staircase I-V-curves or even quantum conductance peaks (sharp current peaks in the I_{sd}-U_{sd} curve, if they are at all seen) in the source-drain I_{sd}-U_{sd}-curve along the QW (meaning not just steps in the conductance I_{sd} as a function of a gate voltage) as in FIG. 3 and especially in FIG. 5 (at room temperature) are seen at room temperature in quasi 1-DEGs not until down to a lateral size of <1-2 nm. Conductance peaks reminiscent of the ones seen here in the Coulomb suppression plateau, however, as a function of U_{gate} (and not of U_{sd} like here) are observed in [7] at extremely low temperatures (100 mK) in QDs (and not in 1-dimensional QWs as here); analogies of the fundamentally underlying theoretical physics (single electron transmission through quantum states, in the references [7,8]) to the here observed effects are still not completely clear, also the theoretical research in [8] describes QDs, not QWs and also only conductance peaks as a function of the gate voltage. In the case of CNTs it is never possible to consider U_{sd} and U_{source-gate} completely independent from each other. As a substrate for the DLC-film in which the QWs are produced by the impact and passage-through of (many) single high energy heavy ions, besides highly doped electrically conductive single crystal semiconductor wafers (in the case of Si-wafer atomically flat) as in [1] also other materials, which are flat on a nm-scale and electrically very well conducting, can be used as a substrate, for instance crystalline metal films (e.g. Au, Pt, Pa, Cu), for instance deposited on mica as a solid, atomically flat support. Ideal would be using a highly doped semiconductor, which would instantaneously form a 2-DEG at the hetero junction with the insulating DLC-film. The same obviously holds/applies for the cover electrode at the upper end of the vertical QWs-array, which however has to be very thin, so that gate field effects can reach all the way down to the embedded QWs, or respectively has to be transparent for optical current modulation of the current through the QWs.

In [1] the lengths of the QW embedded in an insulating film lay in the range of about 100 nm—there determined by the film thickness of the insulating, the wires embedding DLC-matrix layer.

The range of swift heavy ions in the film material is much higher (about 1-5 nm/(keV/nucleon)). The maximum, with realistic effort reachable ion track length in the there used layer matrix (e.g. electrically insulating DLC, perhaps also crystalline SiC) would be about 30 μm at about 11 MeV/nucleon particle energy. At a voltage rejection of about 150 V/μm in DLC [9] a maximum upper limit of the break through voltage of the here invented power transistor would be about 5 kV, of course limited then further by the voltage durability of the QWs themselves, since because of theoretically R≈0 in turn by their current durability, where so far up to about 10 nA per QW (at very few volts) the typical known quantization effects (staircase-I-V-curve) were just still visible. That would in turn mean, that about 1 kA at about a few Volts, i.e. about 1 kWatt maximum controlled power per cm² component area can be reached at ≈10¹¹ QWs/cm².

Another extremely interesting manufacturing method for such a large 2 dimensional array of vertical wires with diameters in the nanometer range (typically 20-50 nm) an area density of also roughly 1 wire per (100 nm)² is claimed/presented in [10], while there the grown nanowires are however significantly bigger in diameter as compared to in [1] and especially here, it is however also mentioned in [10] that 1-2 nm diameters are possible in principle. Although the nanowires in FIG. 7 of reference [10] exhibit—and only at extremely low temperatures (4.2K) however—yet a strongly non-linear I-V-curve showing a broad plateau around 0 Volts, which suggests an influence of Coulomb-blockade effects, but does not demonstrate by far a quantum wire with 1-dimensional ballistic conductivity and staircase characteristics/quantum conductance/current peaks. SWCNTs are however generally accepted as real QWs, but those are much thinner, very few nm in diameter (only ≈1 nm, or even smaller), while there in the measurement in [10] surely the still much wider MWCNTs are present—it is obviously only claimed there (in [10]) a “vertical nano size transistor using CNTs and manufacturing method thereof” and not a QW-array-FET at room temperature, as claimed here for the present invention, not to even mention a 2-dimensional large array of billions of “true” QWs as here in the present invention.

One further extremely interesting manufacturing method of extremely thin (0.4 nm) metallic crystalline nanowires is described in [11]. The electrical characterization of single such wires is to best of my knowledge still lacking, the electrically contacting of such a wire is certainly very difficult.

The here invented quantum field effect transistor would already function at room temperature. Through the B-field dependent phase effects of the electronic wave function it would function significantly more sensitively, if 2DEGs could be realized as source and drain electrodes, even this at room temperature. Then the entity consisting of the 2-dimensional array of parallel (upright standing) QWs and of the ideal metal electrodes/2-DEGs would be a quantum interference device (QUID), which in a wider sense could be regarded as a model system for the understanding of a 1-dimensional (meaning 1-directional) pseudo superconductor at more or less room temperature, i.e. an (1-dimensional—meaning 1-directional) ideal electric conductor with a resulting phase of the superimposed wave functions. The B-field normal to the QWs could perhaps be expelled from the QW-array upon switching on the B-field—because of the phase shifts of the single wave functions with respect to each other in the single QWs short-cut into loops (QUIDS) (see [1])—for which the Aharonov-Bohm effect is taking care of, even though if there were no B-field within the wires themselves at all), while a possible expelling of B-fields within the wires would still have to be clarified [14].

A 1 cm² solar cell of this here invented design, in which through illumination by light (roughly 633 nm) of about 0.5 mW focussed on roughly a spot of 30 μm (where crudely estimated only <1% actually reaches the QW-array surface, since opaqued by the measuring AFM-/STM-probe tip) in a single QW a current of order 0.1 nA is generated, which at a counter voltage of about 0.2 Volts is compensated back to zero. This would at 10¹⁰ parallel QWs per cm² and at equivalently (1 cm²/(30 μm)²)×0.5 mW×0.01=0.5 W optical power deliver a current of 1 A at a DC-power of 0.2 W. That would be roughly an efficiency of 40%. Hereby, it is unclear, as already mentioned above, how large the influence of other possible light sensitive junctions in the set-up really is: Highly doped Si-substrate—graphitic QWs—semiconducting probe tip (highly boron doped diamond).

On its illuminated upper side, the 2-dimensional array of parallel QWs could be interconnected by means of electrically conducting ITO-glass, or for enhancing the efficiency by crystalline and very thin and thus almost transparent metal films. On its lower side the QW-array is connected/interconnected as in [1] by means of a highly doped, electrically conducting semiconductor single crystal or another extremely flat well conductive substrate, ideally forming a 2-DEG with the DLC layer.

### “The Problem”:

In power electronics or very fast microelectronics mainly 2 problems exist: Power losses and degradation through generation of heat and controlling currents as well as long switching times constants. Quantum electronics can solve these two problems while at the same time providing extreme miniaturization, because ballistic electronic conductivity (i.e. the large load current) is running in a quantum transistor/switch without Ohmic resistive losses (R=0 theoretically) as well as the instantaneous, extremely sensitive control/switching signal itself of the quantum electronic element by a field occurs loss-less and practically instantaneous. Controlling the “gate” itself of a quantum transistor has to be mediated by an electromagnetic field (magnetic, electric, optical, or even electro-acoustical) and solely the generation of this small controlling field determines power loss and time constant of this transistor/switch ideally. In addition, in such a quantum mechanical/electronic transistor/switch/relay mechanical contacts (as in a mechanical relay) between gate and the quantum mechanical source-drain element do not exist.

In information storage technology so far only a 1 bit logic is available for the single memory cells (current on or off upon read-out of GMR-harddiscs or respectively capacitor charged or not in DRAMs or both combined in Flash-RAMs); quantum electronics as in the here used quantum wires (QWs) allows a multi-level logic in one memory cell (current on/off in several steps, sharply distinguishable if measurable ideally) and thus a much higher storage density.

“State of the art”:

Power transistors/switches are based nowadays on bipolar (pn-) junctions (thyristors) or optimized MOSFETs with certain power losses and time constants [12].

Even though in MOSFETs 2-DEGs play a role, they are in general not considered quantum electronic transistors, mainly because single electron effects are not occurring, the “grainyness” of the charge carriers does not play a role.

Quantum electronic transistors (single electron transistors—SET) have already been predicted theoretically for a long time and experimentally demonstrated (e.g. [13], [14] and references therein), mostly by solely exploiting the Coulomb blockade (charge quantization) based on the O-dimensional confinement of the electron (size of the QD smaller than the mean free path/scattering length of the electron in the material) in a very small metallic or semiconducting nanoparticle/compartment/“box”, mostly at extremely low (a few Kelvin) temperatures, (but partly also at room temperature in the case of molecules as nanoparticles), gated mostly by a variable static electric field. The overview article in ref [24] by Likharev points out clearly the necessary distinction between mere charge quantization/Coulomb blockade effects from small capacitances and the actual energy level quantization in 0 (or 1) dimension. This is shown in FIG. 5 of [24] for the case of “electron in a small capacitance” where FIG. 5c of [24] would have the same shape if source drain current was plotted against the gate voltage (not against source drain voltage U_{sd}). FIG. 6b of [24] shows then the curve I_{sd} versus U_{sd}, which in my view should show and indeed shows also faint discontinuities in its slope—but not horizontally leveled steps besides the Coulomb suppression regime as in my data—because gate voltage and source drain voltage will mix in terms of stepwise charging up the small capacitance island.

In more recent times also CNTs (where SWCNTs actually constitute quantum wires, as is generally—perhaps/supposedly not always correctly—accepted) and other molecules gated by an electric field have been demonstrated as SETs at room temperature (e.g. [15], [16] and references therein, [17]), but to best of my knowledge, in those cases, there was never observed true transmission through 1-dimensional quantum states (staircase I-V-curve and conductance/current peaks in the source-drain-I-V-curve along the nano wire) at room temperature In [14], actually Aharanov-Bohm oscillations were described within a 1-dimensional metallic cylinder, at extremely low temperatures (about 1 Kelvin) though, which are only visible in an approximately 1-dimensional ballistic conductor. Logic circuitry by usage of CNT-nanowires have been presented already also in [17a].

Nanowire arrays in the form of nano wires electrically connected in parallel, e.g. CNTs, controlled/switched by an electric field (gate electrode) have also already been suggested as power transistors [18], (but significantly before in [23] by myself), but was in [18] so far only realized with some 300 CNTs in a row, which would result in only 3 μA (maximum of 10 nA per nanowire at crudely assumed 100 nm length, roughly the minimum to be able to speak of approximately 1-dimensional conductivity in a nanowire of about a few nm diameter) controllable load current. Quantization effects and their applications are not claimed there (in [18]), the vertical growth method aiming at obtaining 2-dimensional arrays of vertical nano wires as in [18] and similarly proposed in [10], supposedly does not deliver SWCNTs, only the much wider MWCNTs, which do not show any quantization effects at room temperature, at most a moderate Coulomb blockade (solely charge quantization, quite often trivially caused by small capacitances in the junction/material-transition of the electrical contacts, no real 1-dimensional conductance quantization).

Regarding data storage, the generally known state of the art is as follows: In the case of GMR-harddiscs the current through a locally magnetized (writing of the bits) layer is measured by means of a read-write head, and thus the bits are read. In the case of DRAMs and Flash RAMs, the charging state of a very small capacitor is measured via a matrix circuitry similar to a CCD-array. In the case of SD/SDHC-cards, it is closely related to the concept of Flash-RAMs. (Nor-, Nand-architecture).

### Solution:

Quantum electronics can solve these problems concerning power losses/heat generation and time constants and all that by at the same time allowing a multi-level logic with much higher data storage density. This is possible, since ballistic electronic conductivity, and especially the transmission of an electron wave along a 1-dimensional quantum state, i.e. eventually the load current in a quantum electronic transistor/switch occurs without Ohmic resistive losses (R=0 theoretically/ideally) as well as the direct, extremely sensitive control/switching of the quantum electronic elements occurs loss-less and practically instantaneously. The “gate” of a quantum transistor has to be mediated via an electromagnetic field (magnetic, electric, optical, electro-acoustical) and solely the generation of this small controlling field determines power loss and time constant of this transistor/switch. Additionally there is no mechanical contact and no contact voltages in such a quantum mechanical transistor/switch between the gate and the quantum mechanical source drain element and further no leakage currents. Certain contact resistances obviously occur at the (tunnelling-) contact junctions between single quantum wires and the source-drain electrodes, which are in turn necessary, so that the 1-dimensional quantum state is able to exist at all; these tunnelling-transition (contact) resistances have to be at least some or several 10 kOhm, dependent on the tiny capacitance of the single QWs and on the desired sharpness of the quantum conductance/current peaks in the I_{sd}-U_{sd}.curve—at least 25.8 kOhm are resulting from Heisenberg's uncertainty principle. In the case of the here invented power transistor are all these resistances as well as the “resistances” of the QWs themselves (i.e. (reflexion+absorption)/transmission) in parallel, so that the total resistance of these 10¹⁰/cm² quantum wires in such a proposed power transistor and thus the total resistance of the power quantum field effect transistor's source drain connection is thus extremely small.

The here invented power transistor connects about 10¹⁰/cm² vertical and parallel with respect to each other directed quantum wires electrically in parallel and controls the ballistic source-drain current through these nano wires collectively or variably in the single wires. At a current of order of 1 nA through one QW a controllable current of 10 Amperes is resulting at a component size of roughly 1 cm², where the manufacturing method of the quantum wire array [1] in an heavy ion accelerator (e.g. GSI Darmstadt or Ganil/CIRIL, Caen, France) so far at maximum about 25 cm²×10¹¹ cm⁻² (equivalent to roughly 2.5 kA maximum controllable total load current) QWs can be realized, which are electronically independent from each other in the 2-dimensional array. It is emphasized, that the current does not have to be equal in each QW, but also can vary via intended inhomogeneities of the gate field across the total component area and eventually also is supposed to do so. By spatial variation of the gate field the I_{d}-U_{sd}-characteristics of the complete power transistor can be tailored in a certain range. By means of scanning probe microscopy (SPM) or e.g. by means of by SPM structured gate field sources (ferromagnetic or ferroelectric layers—see above) it will obviously be possible to switch only particular single or groups of several QWs in the array specifically, which can be addressed one by one or group by group using micro-/nano-structured electrodes on preferably the “upper” side of the array (see [1]), because on the lower side is the solid support wafer/material but using modern layer technology, the structured side could also be on the lower electrode side in principle. Manufacturing of such minute electrode structures (10 nm-scale) is possible via electron beam lithography or scanning probe lithography, and the newest imprinting methods and optical masking/exposure techniques (XU V) also reach into the 10 nm-scale.

The size limit for the 2-dimensional quantum wire array manufacturing imposed by the design of the heavy ion accelerator is roughly 25 cm² but can be overcome (if necessary at all) in principle using a beam scanning technique [19] at the cost of longer irradiation duration (order of magnitude is about 30 minutes for 10¹¹ single swift heavy ion impacts per cm² instead of only a few minutes normally for 10¹⁰ ion tracks per cm² on a 25 cm²-sample using the ion beam expanded to 25 cm². The QW-density of at maximum about 10¹¹/cm² results in a mean separation of the QWs of about 30 nm from QW to QW. At a particle track diameter of significantly below 5 nm (probably roughly 1-2 nm, probably even smaller, see [1]) and an effective quantum wire diameter of <1 nm (sharp conductance/current peaks at room temperature, FIG. 5), the QWs are then obviously still sufficiently electronically independent. However, it is most likely impossible to position the QWs even closer than that due to electronic overlapping effects and other unwanted radiation damage in the insulating matrix during the generation of the particle track QWs (scattering/impacts with secondary ions/electrons/x-rays) and especially due to larger local radiation damages on/at the surface/interfaces. If, however, a thin source electrode is deposited already before the irradiation with the single swift heavy ions, then the radiation damage at the interface between the DLC-layer matrix in which the particle track QWs form will be certainly less than on a bare DLC-surface and thus a maximum density of the vertical QW-array of 10¹²/cm² is supposedly achievable in principle—however, at regular (as above) fluence of the swift heavy ions' beam the irradiation time duration goes up to about 5 hours, up to date machines certainly have higher beam currents than in 1999 though.

The manufacturing method of the QWs firmly embedded in for instance a DLC-film (as described in [1]) further exploits the here much desired property of diamond of extremely high heat conductance and transparency for light. Thus, in the case that if due to a malfunction in the here invented power transistor suddenly the “Ohm-less” electrical conductivity breaks down in one or many QWs of the large array, due the excellent heat diffusion in the insulating diamond-like matrix, a complete destruction of the power transistor/component probably gets prevented; supposedly only a few single QWs would get destroyed in such a case, which would hardly play a role at 10¹⁰/cm² QWs in the array. Furthermore, of course, a different method for fabricating a 2-dimensional array of vertical quantum wires comprising elongated ideally conducting molecules like cumulenes can be envisioned: Elongated molecules like carbon chains are generally hydrophobic and can always be chemically attached to hydrophilic headgroups or nanoparticles. Thus, using Langmuir-Blodgett or Langmuir-Schafer technique, a 2-diemsional crystal of upright standing molecular chains can easily be produced reaching a density of 10¹⁵/cm²; see also [58]. Thus a 2-dimensional array of vertically densely packed conducting molecules can be formed; the molecules spread on a Langmuir-Blodgett trough can of course be homogeneously mixed with non-conducting molecular chains to ensure an electrical insulation between the (ideally) conducting molecules if desired.

### Solution (Detailed):

A quantum wire array field effect power transistor—here abbreviated as power QFET: A 2-dimensional array of very many densely packed, vertical or tilted up to 30-45 degrees—also in groups with respect to each other—electrically parallel connected “true” quantum wires, which are interconnecting source and drain contacts of this QFET and function at room temperature, collectively or singularly controlled/switched by an electromagnetic field—a quasi-static or a dynamic one respectively. These true quantum wires are fabricated by light ray straight passage of single high energy (heavy) ions (from hydrogen to uranium, from several 100 keV/nucleon to 100 MeV/nucleon, from a positive charge state of 1⁺ to about 60⁺ or negative through an electrically insulating matrix of diamond like carbon or similar electrically insulating matrix material. Hereby also the application of multistable/multilevel switchability is claimed, i.e. the switchability of the quantum transistor in accurate steps as well as the immediate representation of a digitizer simply by counting the well-defined current/conductivity peaks which are equidistant on the voltage axis (FIG. 5) which is a result of the functional features of each single quantum wire, which is—at room temperature—a stair case I-V-curve I_{sd} versus U_{sd} (FIG. 3 at room temperature) and not only versus a gate voltage U_{gate} (in which latter case the Coulomb blockade/charge quantization effects alone would result in a stair case I_{sd}-U_{gate} curve). Furthermore, the functional feature of quantum conductance/current peaks is claimed, which are characterized and manifested in form of extremely sharp peaks in the current I_{sd} in this I_{sd}-U_{sd} characteristics along the true quantum wires in the current suppression plateau in the vicinity of 0 Volts, where the current I_{sd} versus U_{sd} is suppressed as usual by Coulomb blockade but here additionally by conductance quantization effects “along” (i.e. I_{sd} as a function of U_{sd} and not as a function of a gate voltage U_{gate}) the quantum wires (FIG. 5 at room temperature); these source drain characteristics Lₐ versus U_{sd} along such a “true” quantum wire can, however—because they are based on transmission through 1-dimensional quantum mechanical states—nevertheless be very sensitively modulated/controlled/switched by external gating fields (magnetic, electric, electro-acoustic, optical) (FIG. 4—electric, magnetic, electro-acoustic and FIG. 13—optical, all at room temperature) [2,3,4].

In the ideal case of very identically fabricated “true” quantum wires in the 2-dimensional array, these above described source drain I-V characteristics should qualitatively also hold for the entity of electrically parallel connected quantum wires, especially if source and drain electrodes are ideal electric conductors as well (e.g. 2DEGs at room temperature, SCs at low temperatures or as a compromise thin crystalline metal films at moderately lowered temperatures).

The gating of the power transistor can be realized for instance either via an externally applied homogeneous or tailored inhomogeneous B- or E-field collectively gating the entity of said array of quantum wires (FIG. 7, 8, 9, 10, 11) e.g. applied by a scanned probe tip above the quantum wire array structure (FIG. 7) or mediated with memory by a ferromagnetic or ferroelectric layer just on top of the said array of vertical quantum wires (FIG. 8, 9, 10, 11). A more compact design would, however, be realized, if a meander-shaped wiring structure was fabricated into a layer just above the said array of vertical quantum wires (FIG. 3b-I), with the ferromagnetic/ferroelectric layer sandwiched in between, such that the gating current I_{gate} would generate via the inductance of the meander-shaped wire loops a magnetic field controlling/gating the conductance within the entity of quantum wires collectively—eventually mediated via a ferromagnetic layer providing memory effects. Alternatively, electric charges can be brought into close vicinity of the quantum wires through the said meander-shaped circuitry (FIG. 11) thus gating the quantum wires via electric fields, eventually again mediated through a ferroelectric layer providing memory effects. This meander-shaped circuitry (FIGS. 10 and 11) can be fabricated again using the vertical quantum wire array of the present invention and interconnecting the quantum wire terminations interchangingly on upper and lower sides of the DLC-matrix layer using conventional lithography methods, e.g. e-beam lithography or it can be fabricated in a completely conventional way, supposedly just providing structures on a size scale slightly larger than feasible using the said quantum wire array.

Transistor (quantum memory cell), in analogy to patent claims 1. to 7., but in this operational mode characterized by the following:

The source drain current, which is flowing only through one or a few true quantum wires connected in parallel is controlled via external fields and is used as non-volatile (re-) writable stored information, similar to [1]; however, instead of the there used QUID generating an “internal” B-field for the dynamic (i.e. volatile) switching/read-out of the quantum transistor, here now an “external” field generated by an elementary magnet is used for controlling, which is located in an ferromagnetic film or ferromagnetic nano particle above the terminus of the quantum wire and which can be written e.g. by a magnetic tip of a scanning force microscope or by the raster-scanning read-write head of a GMR-HDD. Analogously an E-field gating/control is possible as well as in patent claim 7. This would be a data storage method for a new kind of computer mass storage device, where the electrical current read-out 2-dimensional quantum wire array could be rotating like a current (customary) commercial HDD based on the GMR-effect. The quantum wire array could be stationary as well and one or many parallel read-write probe tips (electrically conductive and at the same time serving as a source for the local magnetic/electric field) could be used.

“Many” probe tips, i.e. an array of probe tips, is a similar case as in U.S. Pat. No. 5,835,477[20]; however, there the stored information is read (and written) exclusively through the cantilever spring/probe tip, whereas here, the probe tips are primarily used only to write and to erase the ferromagnetic/ferroelectric bits controlling the quantum wire currents, which themselves are read out by a stationary “internal” current measurement matrix—similar to a DRAM or flash RAM (just here a current measurement instead of a voltage measurement)—where, however, the quantum wire currents are most easily read out via the conductive probe tips just as in a regular GMR-harddisk. As to how the read out of the quantum wire matrix can be realized by an internal (stationary) current measurement matrix is basically drafted out/indicated in FIG. 23 (as in a Nor-Flash-Ram), where for higher density the connection with a resistor/charge-coupled device cascade matrix similar to those in a DRAM, CCD-array, Flash-RAM would be necessary as in the more densely packed Nand-Flash-Ram.

An alternative for the writing process is shown in FIG. 11 where the meander-shaped wiring for gating the power transistor is broken up into a wiring matrix to address (to gate) the single quantum wires or groups of them either directly or via magnetizing or charging ferromagnetic or ferroelectric nanoparticles deposited above the quantum wire terminations. This meander shaped circuitry (FIG. 11) may be fabricated using the same quantum wire array of the present invention or also conventionally, where in the latter case it will have a slightly larger size scale and thus will be only useful to address (to gate) small groups of the said vertical quantum wires. An alternative for the read-out is shown in FIG. 23, where a crossed nanometric comb structure of conducting leads on the lower side (13a) and the upper side (13b) of the DLC-layer embedding the quantum wires is prepared and serves as a read-out matrix for the conductivity state of the quantum wires, that had been written on before—single connections to each transistor just like in a Nor-Flash-Ram.

Furthermore, because of the functional feature “stair case I_{sd} versus U_{sd} curve” and the quantum conductance/current peaks in I_{sd} versus U_{sd}, a multilevel logic (current step switch and digitizer) becomes realizable and is hereby claimed; as well as mentioned above, simply by connecting a huge amount of quantum wires in parallel, even a multilevel power QFET becomes realizable and is hereby claimed, which is characterized by a very low blockage current (noise floor for the current measurement of single quantum wires is of order pico Ampere).

Patent claim 12 is distinguished and separated from the in the literature many times proposed nano wire FETs, also from the MWCNT-FETs (a FET realized by a single nanowire, eg. a CNT) by the following facts:

Firstly, the here invented single quantum wire transistor is primarily controlled by a magnetic gate field and not by an electric field—however, the here invented transistor can of course be also controlled via a electric gate field as well.

Secondly, a multi level logic is realizable according to the staircase I_{sd}-U_{sd} curves and the quantum conductance/current peak I_{sd}-U_{sd} curves in FIGS. 3, 4, 5 at room temperature and thus Thirdly, here truly at room temperature a 1-dimensional ballistic current (even a transmission current through a 1-dimensional quantum state) through a “true” quantum wire is controlled/gated and not only simply an Ohmic current largely dominated by mere Coulomb blockade effects (single electron effects, i.e. charge quantization but not conductance quantization) with confinement dependent reduced scattering at the walls though in a small but in comparison to the electrons' Fermi wavelength (roughly a few Angstroms in metallic conductors at room temperature) still very large simple nano wire. A nano wire merely based on charge quantization (i.e. without conductance quantization in the I_{sd}-U_{sd} curve) provides a stair case characteristic I_{sd} versus U_{gate} though, but (most likely) no stair case curve I_{sd} versus U_{sd} (FIG. 3) and especially no quantum conductance peaks here manifested in sharp current peaks I_{sd} versus U_{sd} in the Coulomb blocked plateaus and especially in the Coulomb blocked current suppression regime around zero Volts in the I_{sd}-U_{sd} curve along the true quantum wire (FIG. 5). These “unusual” effects are also addressed in [22] in a similar manner, however there, also I_{sd} versus U_{soure-gate} is plotted, while in the here presently invented setup, U_{sd} is also “leaking” into the insulating matrix DLC material, in which the true quantum wires are embedded, and thus accounts for that the sharp quantum conductance/current peaks in FIG. 5 are slowly drifting back and forth on the U_{sd} axis. In other words: U_{sd} and U_{source-gate} are “mixing” in the case of the SWCNTs or the here claimed ideally conducting molecules, or in general the embedded vertical quantum wires here.

All these effects are not affected by DE10036897C1 [21], also not by the nano wire (E-) field effect transistors known from the literature (e.g. [15, 17]) as they do not demonstrate real quantum wires, only charge quantization.

Referring to Major claims 1 and 2:

The here introduced latent particle track quantum wires generated by the impact of swift heavy ions are substantially light ray straight and show a non-linear staircase I-V curve (current I_{sd} along the quantum wire as function of the voltage U_{sd}, and not only a gate voltage) as well as extremely sharp current peaks in this I-V characteristics (I_{sd} versus U_{sd}, not dI/dV versus U) even within the Coulomb suppression plateau. These three features are interconnected as all three are essential to actually having a true quantum wire exhibiting 1-dimensional quantum mechanical electronic transmission current through distinct quantum levels of the strictly 1-dimensional quantum wire, i.e. having an ideal (non-ohmic) conductivity passing a current over a certain (1-dimensional) distance without heat losses and instantaneously manifesting itself in form of these extremely sharp current peaks in the quantum wires I-V characteristics. The overall non-linearity of this electronic component's I-V curve ensures diode behaviour. The overall non-linearity (exponential behaviour) of this I-V-curve would already be caused by mere single electron charging (Coulomb suppression) while the steps and the current peaks in this I-V-curve are due to the presence of true 1-dimensional electronic transmission current through elongated 1-dimensional quantum states.

If the nanowire was bent or curved in any way, it is not truly 1-dimensional anymore and strongly enhanced scattering with the wire's boundaries of the electrons passing through occurs and it can by no means be anymore referred to a single quantum mechanical level being tunnelled through; bending of the quantum wire induces a splitting and a spreading of the quantum levels of the formerly 1-dimensionally elongated electron compartment/potential well.

Only if scattering is essentially fully hindered, it can be related to a true quantum wire which then exhibits the here claimed two functional features of a stepped (staircase) and overall non-linear I-V-curve with extremely sharp current peaks even within the Coulomb suppression plateau.

Thus the quantum wire itself already is a special diode according to its strongly non-linear I-V characteristics (source drain current I_{sd} versus source drain voltage U_{sd}), due to light sensitivity of a quantum wires quantum levels, it also represents a photo diode; further since a gate field of various kinds can be applied to that quantum wire diode and modulates its I_{sd}-U_{sd}-curve, it represents a quantum field effect transistor and since the here introduced quantum wire comes—due to its here presented specific possibility of a fabrication procedure—in a very large array of geometrically ideally parallel vertical quantum wires, even a power transistor can be realized simply by electrically interconnecting very many (of order 10⁹-10¹² per cm²) quantum wires in parallel. Counting the equidistant current peaks in the I-V curve represents an instantaneous digitizer.

Referring to Patent claims 3 and 4:

(Power) transistor, (power) switch, photo-detector, or solar cell, specified in that it is: A quantum wire array power transistor (QFET—quantum field effect transistor): 2-dimensional array of very many densely packed (10⁹-10¹²/cm²), vertical or in particular up to 30-45 degrees—also in groups with respect to each other—tilted, in an insulating matrix embedded parallel and—also in groups—electrically parallel connected quantum wires (QWs), which interconnect source and drain contacts of the QFET and function at room temperature, collectively controlled/switched or one by one wire/wire-group by a electromagnetic field (static or dynamic). Especially it is hereby claimed, that the so manufactured as in [1] quantum wires exhibit in particular at room temperature a here in this invention usable/applicable staircase-I-V-curve along the quantum wire (i.e. source drain current I_{sd} along the QWs as a function of the source drain voltage U_{sd}, FIG. 3 at room temperature), not just as a function of a gate voltage U_{g} (which could already be caused by mere Coulomb blockade effects, i.e. mere charge quantization effects as opposed to quantized conductance/transmission through 1-dimensional quantum states). Especially it is further claimed the occurrence and usage in this invention of the quantum conductance/current peaks (here manifested in form of extremely sharp peaks in the current I_{sd}) in this I_{sd}-U_{sd}-characteristic (measured along the “true” QWs) even within the current suppression plateau (in the vicinity of 0 volts, where the current I_{sd} versus U_{sd} is suppressed as usually by the Coulomb blockade—but here also by the conductance quantization effects) (FIG. 5, at room temperature) “along” the QW; quantum conductance/current peaks are sometimes also visible at higher voltages U_{sd} outside the Coulomb suppression plateau. These source-drain characteristics I_{sd} versus U_{sd} “along” such a “true” quantum wire can be very sensitively and rapidly modulated/controlled/switched by applied external “gating” fields (magnetic, electric, optical, electro-acoustical)—FIG. 4 electrically/magnetically/electro-acoustically and FIG. 13 optically, all at room temperature—, because they are caused by 1-dimensional transmission through quantum states [2,3,4].

If these “true” QWs in an 2-dimensional array are manufactured very identically either in form of SWCNTs or in form of straight poly-acetylene-reminiscent molecules of the cumulene form . . . ═C═C═C═C═C═C═ . . . or of the mesomeric form . . . —C≡C—C≡C—C≡C— . . . , these characteristics in the source-drain I_{sd}-U_{sd}-curve of a single QW should also qualitatively occur in the entity of the electrically parallel connected QWs, especially if source and drain electrode are ideal conductors as well (e.g. 2-DEGs at room temperature, SCs at low temperatures or as a compromise thin crystalline metal films at moderately lowered temperatures).

Fabrication of these quantum wires is performed by irradiating a thin film of DLC (thickness ranging from 50 nm to 30 μm) with single swift ions ranging from hydrogen ranging to heavy ions like lead and uranium at a positive charge state ranging from ⁺1 to ⁺60 at kinetic energies of several 100 keV/nucleon ranging to 100 MeV/nucleon.

Furthermore, of course, a different method for fabricating a 2-dimensional array of vertical quantum wires comprising elongated ideally conducting molecules like cumulenes can be envisioned: Elongated molecules like carbon chains are generally hydrophobic and can always be chemically attached to hydrophilic headgroups or nanoparticles. Thus, using Langmuir-Blodgett or Langmuir-Schafer technique, a 2-dimensional crystal of upright standing molecular chains can easily be produced reaching a density of 10¹⁵/cm²; see also [58]. Thus a 2-dimensional array of vertically densely packed conducting molecules can be formed; the molecules spread on a Langmuir-Blodgett trough can of course be homogeneously mixed with non-conducting molecular chains to ensure an electrical insulation between the (ideally) conducting molecules if desired.

Referring to Patent claim 5:

Power transistor according to patent claim 1-4, specified in that, that:

the source-drain current is modulated/controlled/switched via a magnetic field by means of variable current in a coil surrounding a soft iron core tip (or structured), spatially closely above the QW array, as well as by its distance to the QW-array (FIG. 7) or by the current through a meander-shaped conducting lead closely on top or underneath the QW-array or embedded within the QW-array which partly surrounds each QW-termination and thus induces through the inductance of these wire loops a magnetic field upon each QW (FIG. 10, 11 with or without the memory effect provided by the ferromagnetic/ferroelectric layer sandwiched in between).
Referring to Patent claim 6:

Power transistor according to patent claim 1-5, specified in that, that: the source-drain current is modulated/controlled/switched via a magnetic field by means of depositing and appropriately magnetizing (e.g. by writing onto using a magnetic tip as in claim 5 mounted to a SPM) a ferromagnetic layer on the 2 dimensional quantum wire array, e.g. Fe, Co, Ni, etc. or a layer from polarizable ferromagnetic nanoparticles (Fe, Co, Ni, etc.), i.e. a power transistor with non-volatile memory effect of the transistor-working point and the source-drain-I-V-characteristics (FIG. 8, 9, 10, 11). A better more compact design obviously is using the said meander-shaped circuitry in close vicinity to the said array of vertical quantum wires with the ferromagnetic/ferroelectric layer sandwiched in between (FIG. 10), such that the magnetic field generated by I_{gate} driven through the inductance of the said meander-shaped circuitry is magnetizing the ferromagnetic nanoparticles and thus their field is gating the entity of the array of quantum wires in a tailorable way. Analogously with electric fields using the concept in FIG. 11—see claim 7.

Referring to patent claim 7:

Power transistor according to patent claim 1-4, specified in that, that:

the source-drain current is modulated/controlled/switched via an electric E-field by means of an electrically (statically) charged scanning probe tip or by means of depositing onto or embedding into the 2 dimensional QW array and appropriately polarizing (i.e. by means of an electrically strongly charged tip mounted to an SPM) of a ferroelectric as well as alternatively an antiferroelectric layer, or by means of applying a lateral voltage (electric field) in this polarizable (thin) film, for instance an appropriate liquid crystal layer of polar molecules or of a layer of polar nanoparticles, equivalent to the magnetic case in patent claim 6 with non-volatile memory effect of the transistor working point and the source drain-I-V-characteristics (as in FIGS. 7 and 8-11). Alternatively, the meander-shaped circuitry can be used as well to bring electric charges into close vicinity of the quantum wires, e.g. by charging ferroelectric nanoparticles deposited in form of a ferroelectric layer sandwiched between the quantum wire array and the meander-shaped circuitry (FIG. 10 and especially FIG. 11). Again, the meander-shaped circuitry can be itself be fabricated based on such a quantum wire array of the present invention or conventionally on a slightly larger size scale.
Referring to Patent claim 8:

Power transistor according to patent claim 1-4, specified in that, that: the source-drain current and its I_{sd}-U_{sd} characteristics is modulated/controlled/switched by means of irradiation/illumination an electromagnetic field (e.g. IR-light, visible light, UV-light, X-rays) onto the 2-dimensional QW-array (photodetector) (FIG. 12).—according to light sensitive I-V-characteristics of a single QW (FIG. 13).

Referring to Patent claim 9:

Power-quantum wire array solar cell in design and fundamental function identical with patent claim 1-4 and patent claim 8 which is specified in that that: under exposure to light at 0 Volts U_{sd} is flowing a non-zero current I_{sd} which means light energy is converted into electrical energy.

Referring to Patent claim 10:

Artificial retina comprising an array of quantum wires (QW) electrically contacted: The QWs in the array are electrically contacted one by one, the “light-effect” on the single drain current in single QWs in the extremely large and dense array (up to 10¹⁰-10¹² QWs per cm²) is read out dependent on the location of the single illuminated QW and thus can be used in highest resolution electronic cameras. Using modern (current) lithography methods the necessary small structure widths can be realized theoretically, for instance in order to manufacture a resistor/semiconductor junction cascade as in an shift register. One conceptual way for tuning the light sensitivity of the quantum wires by gating the conductivity via an external field is shown in FIG. 23, one conceptual way for mass fabrication of a read-out matrix with single lead connections to each quantum wire photo transistor/diode is shown in FIG. 23. For both concepts, it is also possible to adjust the design such that small groups/entities of several parallel quantum wires are addressed collectively by one single lead connection. Hereby, the separate contacting of the single quantum wires should be realized as in a charge coupled device or a Flash-RAM, where a horizontally crossed comb structure of nanometric wires ((13a) and (13b) in FIG. 10) is prepared on the upper and lower sides of DLC-layer (2) and the surface density of swift (heavy) ion hits is adjusted just above the area density of the wire crossings such that on average every connecting wire crossing is interconnected by one ion track quantum wire (1a) or where the surface density of swift (heavy) ion hits is adjusted well above the area density of the wire crossings such that on average each connecting wire crossing is interconnected by several parallel ion track quantum wires.

Referring to Patent claim 11:

Power transistor, power switch, or solar cell according to patent claims 3-9, specified in that that:

source and drain electrodes consist of an ideally conducting layer (e.g. crystalline metals at moderately low temperatures, super conductors at low temperatures or 2-DEGs at room temperature), where through phase shift effects of the electronic wave functions in the quantum wires the sensitivity/efficiency of the transistor gating/gain respectively the solar cell's yield efficiency can be enhanced. This further represents a model system for a 1-dimensional/1-directional pseudo-super conductor at (at least almost) room temperature although has nothing to do with Cooper-paired electrons; it is an at room temperature ideally conducting quantum interference device comprising billions of collectively coupled quantum wires with possibly similar physical properties as a superconductor as the energy band separations in a quantum wire are in the mVolt range as is the band gap of a conventional superconductor.
Referring to Patent claim 12:

Transistor (quantum memory cell, QMC) analogously to patent claims 1 to 7., specified in that that:

the source-drain current of only one or a few parallel connected “true” quantum wires (QWs) is controlled/switched and is used as a non-volatile, (re-) writable memory cell, similar to the proposal in [1], but differing in that that instead of the B-field generating QUID there for dynamic (i.e. volatile) switching/writing/reading out of the quantum transistor, here now an “elementary magnet” in a ferromagnetic film or a ferromagnetic nanoparticle above one terminal of the QW/QWs is used for the writing of the conductivity-state of the QW/QWs, which could for instance be “set” magnetized by the magnetic tip of an SPM, or by the writing head of a HDD—analogously, an electric field “setting” of the QWs' quantum states as in patent claim 7 is possible. This would be a storage technique for a new-fashioned computer mass storage device, where the 2-dimensional QWs'array read out by measuring currents through the single QWs or small groups of parallel QWs could be rotating underneath a (current) reading head just like in up-to-date on GMR-effect based HDDs; or, a stationary read-out would be possible using one or many parallel write/read scanning probe tips (electrically conducting and simultaneously serving as a source for a local magnetic/electric field). “Many” probe tips, i.e. an array of probe tips is similar to [20], but there, the stored information is exclusively read (and of course also written) via the cantilevered probe tip, while here in the present invention the probe tip(s) are primarily serving only for writing and erasing of the QW-currents-controlling ferromagnetic/ferroelectric bits (with multilevel logic eventually). Further the QW array can also be read out via a stationary “internal” current measuring (matrix) integrated on or into the QW-array—similar to the read-out method in a DRAM or Flash-RAM (here just a current detection like in a Flash-Ram instead of a voltage detection)—while however obviously the currents through a QW can be measured most easily via electrically conductive probe tips, analogously to a currently used GMR-HDD. A way, how the read-out of the QW-matrix via an internal current measuring matrix can be realized, is described/suggested in [1], where still the connection with a resistor or semiconductor junction cascade matrix probably similar to the one in a DRAM, (Nand-) Flash-RAM, CCD-array is needed. A further, more integrated way for the read-out but especially for the writing of the bits into the quantum wire memory cells is suggested in FIG. 11. The meander-shaped conductive lead structure of claims 5 and 6 broken up into single wire loop inductances (FIG. 11) can be used to write onto the single quantum wire or quantum wire group transistors by either controlling the quantum wires' conductance directly or via magnetizing the ferromagnetic nanoparticles deposited above the quantum wire terminations, where the same can be realized equivalently with ferroelectric/antiferroelectric nanoparticles where the wire loops would charge them electrically. Hereby, for the mere read-out, the separate contacting of the single quantum wires should be realized as in a charge coupled device (CCD or Nand-Flash-Ram) or as in a Nor-Flash-RAM, where a horizontally crossed comb structure of nanometric wires ((13a) and (13b) in FIG. 23) is prepared on the upper and lower sides of DLC-layer (2) and the surface density of swift (heavy) ion hits is adjusted just above the area density of the wire crossings such that on average every connecting wire crossing is interconnected by one ion track quantum wire (1a) or where the surface density of swift (heavy) ion hits is adjusted well above the area density of the wire crossings such that on average each connecting wire crossing is interconnected by several parallel ion track quantum wires.

By means of the staircase characteristic (I_{sd} versus U_{sd}-curve) and the quantum conductance/current peaks in I_{sd} versus U_{sd} a multilevel-logic becomes realizable, using many parallel quantum wires perhaps a multilevel-power quantum field effect transistor (power QFET) becomes realizable, which is characterised by an extremely low leakage/rejection current. The noise floor for the current measurement is of order pAmpere.

Non-volatility for this here invented QMC is not quite analogous to DRAM (volatile) and Flash-memory (non-volatile), because at switched off power supplies the as currents stored (order nanoAmperes) information temporarily disappears, but the working point on the I_{sd}-U_{sd} characteristics remains stored in an non-volatile manner due to the ferromagnetic/ferroelectric (locally “written” by structuring the gate) gate and is immediately accessible again, once the power is switched back on, of course only at exactly the same U_{sd}, where such a here invented multilevel power transistor (quantum FET) could serve as a stable and super accurate power supply. But conceptually the same holds for a Flash-Ram, just here in the present invention due to the quantization effects, a more accurate power supply is needed, as suggested here. Patent claim 12 differs and is distinguished from the multiply in the literature suggested nanowire-FETs, also from the (MW)CNT-FETs (a FET realized by a single nanowire/quantum wire—e.g. a CNT) in that that:

Firstly the here invented singular quantum wire transistor can be controlled/gated by a magnetic field and not just by an electric field (the present invention transistor of course can also very well controlled/gated by an electric field), Secondly, a multilevel logic according to the staircase and the quantum conductance/current peaks in the I_{sd}-U_{sd}-characteristics in FIGS. 3, 4, and 5 at room temperature is realizable, and thus

Thirdly, in that that here actually in fact at room temperature a 1-dimensional ballistic current (even transmission current through a 1-dim. quantum state and not through a zero-dimensional quantum dot]) through a “true” quantum wire is controlled and not—as in most of the literature—just largely an Ohmic current is observed superimposed by Coulomb blockade effects (single electron effects, i.e. mere charge quantization, not conductance quantization) with due to confinement somewhat reduced scattering at the walls of the nanowire, which is very small in diameter though, but in comparison to the Fermi wave length (roughly a few Angstroms in metallic conductors at room temperature) of the electron the nanowires' lateral dimension is still huge, at least at room temperature (in a metal, scattering length/mean free path goes up with decreasing temperature, Fermi wavelength remains the same)—whereas in a true quantum wire its lateral dimension has to be of order of the electron's Fermi-wavelength in the material which to first order is not temperature dependent. A nanowire just based on charge quantization (i.e. without conductance quantization in the I_{sd} versus U_{sd} characteristics) supplies a staircase curve I_{sd} versus U_{gate} but (most likely) not a staircase curve I_{sd} versus U_{sd} (FIG. 3 with quantum wire, compare to FIG. 6 without quantum wire) and by no means quantum conductance peaks (here manifested by extremely sharp peaks in the current I_{sd}) in the Coulomb blocked current suppression plateau around zero Volts as visible in the I_{sd} versus U_{sd} characteristics along the here shown “true” quantum wire (FIG. 5). These “unusual” effects are also addressed in similar manner in [22], also there I_{sd} is plotted versus U_{source gate}, where in the set-up of the present invention also it can be assumed, that U_{sd} is leaking into the electrically insulating matrix and is responsible for the fact, that the quantum conductance/current peaks are slowly drifting back and forth along the U_{sd}-axis. In other words: U_{sd} and U_{source-gate} “mix” in the case of CNTs (always, and the more the shorter the quantum wires are).

All these effects are not touched in [21] for instance, neither in work, known from the literature, on nano wire (E-) field effect transistors (z.B. [15], [17]).

Referring to Patent claim 13:

The experimental set-up in FIG. 1 (see also FIGS. 15-22) for the recording of the characteristic I_{sd}-U_{sd}-curves of single quantum wires contains a protective resistor (8) between the combined STM/AFM-probe tip and the function generator which is the voltage source for U_{sd}. The chosen resistance depends on the specific tip and quantum wire properties and lies in the ranges of roughly 100 kOhms—1 Mohms or 1 Mohms—10 Gohms. The measurement procedure is described in the figure caption of FIG. 1.

The energy band model in FIG. 21 hence describes the physical situation as to why measurements of the quantum wires' energy level states can be accessed and resolved in the mV-regime at room temperature in a simple I-V-curve: The tip carries a quantum dot or the hillock shaped ion track terminations serve as quantum dots by means of which a double resonant tunnelling electronic link/bridge is constructed and is thus filtering/“funnelling” the quantum wires' energy levels which usually (when using direct ohmic tunnelling contacts to and from the quantum wires) would be smeared out by the thermal energies (of 25 meV). Thus the electrons tunnel from the (conductive) tip material into the (first) quantum dot with its energy levels between tip and quantum wire which leads to a first resonant tunnelling “diode” and to a first energy gap (shown in FIGS. 6, 17 and schematically in FIG. 21) as usually seen at room temperature when using mere ohmic contacts to and from the quantum dot) and then this first sharp energy level state (its HOMO/LUMO) which is not visible “alone” at room temperature in an I-V curve (again see FIGS. 6, 17 and schematically in FIG. 21) scans (the voltage scan while recording the I-V curve) the evenly spaced sharp energy levels of the quantum wire in the mV-range. Hence through this second resonant tunnelling “diode”, these 2 mV-spaced sharp energy levels of the quantum wire become visible even at room temperature in this double resonant tunnelling I-V-curve, while higher states of the quantum dot are far away (in energy) as the small quantum dot's energy levels are roughly spaced by roughly order eV, not meV, but they are also intrinsically extremely sharp as meV, just not visible alone (using ohmic contacts to and from the quantum dot) in an I-V-curve at room temperature.

It is again emphasized that this is made possible by the intrinsic quantum mechanical energy levels in the quantum dot and/or the quantum wire respectively; mere Coulomb blockade/charging effects cannot explain the situation.

### APPENDIX

### Abstract

An array of parallel quantum wires embedded vertically in an insulating diamond-like carbon (DLC-) thin film (˜100 nm) on a highly doped silicon wafer (kindly provided by [49,50], see below) has been demonstrated and characterized at room temperature by atomic/scanning force microscopy (AFM/SFM) with a conducting probe tip, showing Coulomb blockade and negative differential resistance. The nano-wires had been fabricated by vertical passage of 4.4 MeV/nucleon and highly charged Pb⁺⁺ ions through the film (performed by M. Toulemonde at GANIL, Ciril, Caen, F), each ion leaving one electrically conductive latent track in the film behind. I-V curves (current as a function of the voltage along the wire, not as a function of a gate voltage) through single tracks—truly 1-dimensional quantum wires—showed the typical staircase behaviour on a 100 mV scale but also very sharp current peaks even within the Coulomb suppression plateau on the mV horizontal scale, being reminiscent of or even representing a quantum wire's DOS.

Introduction

Nanowires, and in particular quantum wires have been subject of very intense research for many years in the visionary field of quantum and molecular electronics [25,26] and has—besides semiconductor/MBE fabrication of 2 DEG's with gate electrode confinement to 1 dim wire structures (e.g. [27])—rapidly progressed since showing of single molecular electrical contacts [28] and since the discovery of carbon nanotubes (or also fullerenes) as electrically conductive nanowires or also nanoparticles [29,30]. Very recently, several ways of fabricating arrays of densely packed, vertical nanowires have drawn wide attention where both molecular [31] and metallic [32] concepts were shown. Here, high energy heavy ion technology (e.g. reviewed in [35,36]) was used to fabricate such an array of vertical nanowires embedded in an insulating DLC-film on a doped Si-wafer and the single wires' quantum-mechanical electronic conductance could actually be proven (see also [33,34]) and characterized in detail at room temperature in ambient conditions using AFM with a conducting probe tip:

When single high-energy (order GeV) and highly charged (20⁺ to 50⁺) heavy ions (e.g. Au, Pb, Bi) impinge on solid surfaces, they induce long (several 10 μm) and very thin (primary diameter of a few nm) cylindrical, very homogeneous but drastic material modifications, called latent ion tracks. Here, for a thin target film and although still non-relativistic incident kinetic energy E, the scattering cross sections and (dE/dx)/E are small and mainly constant along the track [35,36]. dE/dx here being the energy loss, typically of order keV/nm to keV/A, E typically 1.4-11.4 MeV/n (well above the threshold for nuclear collision not to occur throughout the DLC-film). Typical primary latent track diameters (upper limits) are about 5-10 nm or smaller e.g. determined by small angle x-ray scattering [37] or AFM [43,44,48] and can often be extremely anisotropically chemically etched [35,36] e.g. to form nm-diameter scale many μm long hollow channels e.g. for ultrafiltration (nucleoporefilters), for studying electrolytic currents through nm-scale pores [38] or generating small metallic wires inside by filling the pores electrochemically [39]. With a so-called “heavy ion microprobe” [40] such tracks can be generated one at a time at predefined micrometer scale lateral positions.

There is two limiting case theoretical concepts describing the track formation by swift heavy ions passing through solids: 1) Thermal spike model [41]—a statistical model mainly for describing the limiting case situation in a metal. 2) Coulomb explosion [36]—a mechanistic model as the limiting case for describing the situation in insulators. In the case of the here investigated diamond-like carbon (DLC-) 100 nm film (see below), which gets passed through by the ion in about 10⁻¹⁴ seconds, the insulator limiting case would have to be considered, also since and even though these insulating DLC films are transparent [42] in the IR regime.

Realization of nano- and quantum wires embedded vertically in insulating films or foils by formation of super-fine electrically conductive latent ion tracks without need for further treatment (etching, metallic filling etc.) e.g. by locally graphitizing the carbon in the polymer or SiC [43,44,45]—unsuccessful so far in terms of conductivity for the case of PI, PET and SiC- or diamond has also been an inherent idea for a while also e.g. at HMI Berlin, FRG and JAERI Tagasaki, Japan [46], and has also more recently been attempted using such DLC—thin films [47]. The so far existing data could not yet show well-defined currents as was measured here now (see also [33,34]), since voltage breakthroughs originating from extreme electric fields at sharp conductive AFM-tip asperities might occur in thin films although not observed in 4 μm thick PI and PET [45].

Materials and Methods

Extremely flat (roughness well below 0.1 nm) DLC-films grown to a thickness of roughly 100 nm on a highly doped Si-wafer were kindly provided by T. Wittke and B. Schultrich, from the IWS in Dresden, FRG [49] and H. Hofsaess group, Univ. Göttingen [50]. Conductive AFM probe tips (boron doped diamond film on a single crystalline silicon cantilever with integrated tip) came from Nanosensors, Wetzlar, FRG [51]. Elasticity effects/artifacts should be negligible here on this hard DLC-film as opposed to when making the same efforts on rather soft polymeric films [43,44].—however, even here such effects were observed (see below). Swift heavy ion (Pb⁺⁺ at 4.1 MeV/nucleon) irradiation on these 2 substrates was performed at GANIL, CIRIL in Caen, France by M. Toulemonde, where an accumulated dosis of 10⁻⁹/cm² was applied, meaning that there is roughly ten ion tracks per 100×100 nm² on the sample. The ions were highly charged, roughly about 20⁺ to 50⁺ (see also [43,44]), where the exact charge state equilibrates anyhow after the Pb⁺⁺-ion has passed the 3-foil detector—in which the charge state roughly doubles [43] from the initial value of approx. 20⁺—and after it has passed the first few 1-10 nm in the target (typical dE/dx=keV/nm to keV/A) to a here unknown value.

Results and Discussion

FIG. 15 shows AFM-topography (FIG. 15—left) and current image (FIG. 15—right) of the irradiated thin film preparation on a conducting silicon wafer. The single latent ion tracks are clearly visible as protrusions roughly 1 nm in height and roughly 10 nm in apparent diameter. The 1:1 correspondence of the track locations in both simultaneously recorded micrographs is emphasized. The average resistance (1/conductivity) is of order 1 GΩ here at a few 100 mV applied voltage of either polarity—for illustration purposes reversed roughly in the middle of FIG. 15—right. The mean grey level corresponds to zero current (resolution ˜10 pA). The topography image in hexane and heptane oil ([45], data not shown) is of higher quality (AFM can function more stable and with smaller loading forces in a liquid) and the track terminations appear even sharper. At a nominal tip radius of 100-200 nm of the used cantilever tips, the ion track terminations should appear much more broadened, but since the sample surface is extremely (practically atomically) flat in the AFM images and the doped CVD/PVD diamond coating on the tip usually consists of small crystalline grains/microcrystals [51] a single imaging asperity can (and must) be serving as a very sharp “local” mini-tip.

The specific structure and chemical composition of these latent ion tracks in DLC-films remains to be clarified by future research, as is e.g. ongoing in detail for the case of ionic crystals [48, 44] and polymers [43,44,52]. It may well be that carbon nanotubes or special poly-acetylene-like molecules or even cumulenes might have formed here due to the extremely high energy density anisotropically deposited by the surpassing fast ion.

Here, in contrast to [47], current could be measured even down to and below a few 10 mV voltage applied and the protrusions were observed at all and already in ambient air before applying any voltage to the tip, largely ruling out any kind of “accidental” tip-field induced material deposition [45] or simple voltage breakthroughs through a thin film. Arcing through the thin film—as observed in some irradiated polymers [53] or local currents along ion tracks could not be reproduced (noise floor ˜10 picoamperes) at all anywhere on 4-6 μm thick PI and PET foils [45] up to 300V applied tip voltage. The foils were Au or Au/Cr coated on back side before and/or after the (same kind as above) irradiation—here, in air, as opposed to water or alcohol [43,44], the tracks weren't directly visible to the AFM however. Other DLC-substrates of same kind and similar fabrication (Hofsäβ group Göttingen) showed the same kind of protrusions, a factor of 4 higher though (˜4 nm), ([45], data not shown). Here, the resistance went down to order 10 MOhms and light sensitivity (the 670 nm AFM detection laser diode) throughout the I-V curve was found (FIG. 16). Even around zero-voltage about a few 0.1 nA were detected under illumination. This photoeffect—although measurable only localized on top of such a track termination (zero current elsewhere) may perhaps not be localized to the single conducting tracks but could be also due to non-linear optical wavelength down-conversion effects in the silicon wafer sample contacted at the back-side at rather high incident light intensities [54]—Si is transparent for IR light [51, 54]. However, there was no such photoeffect in the irradiated “Dresden” silicon sample of FIGS. 15, 17-22 at all, and of course, no current at all (noise floor ˜10 pA) anywhere off the tracks in either sample.

Due to strong and most likely variable (lateral tip drift) local fields near the sharp tip and sharp ion track peaks as well as local material and geometry dependent Fermi-level differences, the effective electric field parameter at the tip-sample contact resulting in the true local (nm-scale) contact potential difference in an I-V curve will probably not exactly be the same as the voltage applied externally (the tip is here always in contact as opposed to STM.)—Simply the true voltage axis of the I-V curves may be shifting slightly back and forth as the tip slowly drifts across the ion track surface termination. This may be one hypothetical reason for the often “noisy” appearance of the I-V curves shown in FIGS. 17-22:

FIGS. 18 and 19 now show I-V curves measured on single ion tracks, clearly demonstrating “steps”, i.e. discrete current levels at room temperature in ambient atmosphere—see also [33,34]. The typical staircase is very pronounced only for the first one or two steps usually and then appears “fuzzy” mainly because here only a few of consecutive instantaneous I-V cycles can be recorded at satisfactorily precisely the same sample location within the nm-scale track diameter—(lateral tip-drift of order nm/minute while recording the I-V-curves at a cycle rate of about 50 Hz). The first step (at about O˜100 mV) appears flat, the higher steps show pronounced negative differential resistance presumably just like in Esaki tunnelling, i.e. “hot” electrons arriving at the target electrode above the Fermi level and then relaxing via electron-phonon scattering. Exceeding tip voltages above 1V mostly resulted in severe degradation effects.

I-V curves have been recorded using the same tips on conducting diamond films—the cantilever chip with conducting diamond coating itself as a sample [45] and the currents were about 3 orders of magnitude higher (and “jumping around” by more than one order of magnitude) at same applied voltages and “steps”—although did occur—were observed in a very erratic and inconsistent way, sometimes even large accounting for very small grains at the tip (FIG. 17). In FIGS. 18, 19—although the characteristic shape of the staircase curves switched back and forth significantly over time (due to slow tip drift)—the overall slope (resistance) reproduced well as long as the tip was on the track as did the step widths and positions on one and the same track termination. The negative differential resistance regions in FIG. 18 can most likely not be caused by the tip grains as in FIG. 17, since if a GigaOhms ohmic wire resistance were simply in series with the IV-curve of the tip material itself, those “peaks” of FIG. 17 would disappear in the noise. Thus there must be two Coulomb blockade “islands” in series here.

The inset in FIG. 19 (enlarged view presented in FIG. 20) shows around zero voltage (within the Coulomb current suppression) extremely sharp current peaks (see also [55]) of order a few 0.1 nA to 0.5 nA, even up to 1 nA with a spacing of roughly about 2 mV on the horizontal voltage axis, which were occasionally observed. It is noted that I(V) is displayed, not dI(V)/dV. Most likely due to the above hypothesized true local contact potential variations and a floating “gate voltage” (as the embedded wires were not contacted from the side), these peaks were moving back and forth on the voltage axis, however remaining in exactly constant voltage spacings with respect to each other. The inset of FIG. 19 (FIG. 20) shows two such “pulse trains” (forward and backward trace on the Hameg oscilloscope) superimposed which are displaced by roughly 1 mV. Hypothesis for this observation of on the voltage axis evenly (about 2 mV spacing) spaced quantized conductance peaks might be as follows: It may actually be the case that this—and not only a staircase—indeed is the expected I-V-characteristics of a true quantum wire like a single walled nanotube or a special poly-acetylene-like molecule or a cumulene—i.e. current flow where electron scattering is completely ruled out (note that in a mere ballistic conductor elastic and coherent scattering is still possible). Also grounding a quantum wire via an IVC smears out its density of states even though the rule of thumb [25] (from Heisenberg's principle) for seeing quantum effects (R>h/e²=25,8 kΩ) at all is met by the high gain impedance (10⁸Ω) and wire capacitance (represented by the step width in FIGS. 18, 19). For seeing the sharp conductance peaks, the minimum contact resistance to the quantum wire may have to be scaled up to R>6.45MΩ. At voltages applied larger than the energy spread of one wire's quantum levels, the current cannot be flowing within one level but has to cascade down between two or more levels—like in Esaki tunnelling, but here passing through quantized levels—inelastic electron-phonon scattering in an quasi-continuous energy band should not really exist in a nanowire (ballistic and true 1-dim), thus these current peaks should in fact be very sharp, if the tip's Fermi level weren't broadened by Eₜₕ˜25 meV here at room temperature. On the tip side, however, a small conducting nanoparticle or a thin (local) 2 DEG will form a resonant tunnelling diode whose first energy state could be above 25 meV (if the effective size <<5 nm), which could be possible according to the Coulomb blockade observed with the tip material only (FIG. 17) Such a “nanoparticle RTD” would act as an energy filter allowing the spectroscopic resolution of <<0.1-1 mV at room temperature, which may have been the case here incidentally, but should result in a widely applicable concept. A simple energy band model for this experimental observation of such sharp conductance/current peaks in the I-V-curve along such a quantum wire as shown in FIG. 19—inset (FIG. 20) is proposed in FIG. 21:

The energy band model in FIG. 21 hence describes the physical situation as to why measurements of the quantum wires' energy level states can be accessed and resolved in the mV-regime at room temperature in a simple I-V-curve: The tip carries a quantum dot or the hillock shaped ion track terminations serve as quantum dots by means of which a double resonant tunnelling electronic link/bridge is constructed and is thus filtering/“funnelling” the quantum wires' energy levels which usually (when using direct ohmic tunnelling contacts to and from the quantum wires) would be smeared out by the thermal energies (of 25 meV). Thus the electrons tunnel from the (conductive) tip material into the (first) quantum dot with its energy levels between tip and quantum wire which leads to a first resonant tunnelling “diode” and to a first energy gap (shown in FIGS. 6, 17 and schematically in FIG. 21—upper part) as usually seen at room temperature when using mere ohmic contacts to and from the quantum dot) and then this first sharp energy level state (its HOMO/LUMO) which is not visible “alone” at room temperature in an I-V curve (again see FIGS. 6, 17 and schematically in FIG. 21) scans (the voltage scan while recording the I-V curve) the evenly spaced sharp energy levels of the quantum wire in the mV-range. Hence through this second resonant tunnelling “diode”, these 2 mV-spaced sharp energy levels of the quantum wire become visible even at room temperature in this double resonant tunnelling I-V-curve, while higher states of the quantum dot are far away (in energy) as the small quantum dot's energy levels are roughly spaced by roughly order eV, not meV, but they are also intrinsically extremely sharp as meV, just not visible alone (using ohmic contacts to and from the quantum dot) in an I-V-curve at room temperature. It is again emphasized that this is made possible by the intrinsic quantum mechanical energy levels in the quantum dot and/or the quantum wire respectively; mere Coulomb blockade/charging effects cannot explain the situation.

From those large current peaks (up to 0.5 nA or 10⁶e⁻ per sec, even up to 1 nA) within the current suppression plateau around 0 volts it is further speculated that the electronic charge is “invisible” for the electrons to each other while the electrons are in the quantum wire “tunnel”.

FIG. 22 shows sharp and distinct (probably only time dependent, not voltage dependent) current oscillations symmetrically around or enveloped by the typical “staircase” I-V curve (FIGS. 18, 19) with oscillations down the horizontal axis to I=0 even, which often occurred spontaneously but could also be acoustically excited. A gentle oscillation of the AFM's force feedback which could result in contact resistance variation is involved but: 1) If it is a contact resistance/capacitance effect, then the staircase shape cannot be caused by a such trivial effect as the step width and height remains roughly constant during that current oscillation around or enveloped by the constant I-V staircase; which is roughly the same as in FIG. 8. 2) The current oscillation is perhaps caused by a very subtle physical origin—like quantum interference effects where phases are acoustically modulated [56] most likely involving B-fields from the relatively strong sample holder magnet, reminiscent of DC-Josephson effect—see also [25]—or involving electric fields from the scanner piezo.

From the I_{source-drain} versus U_{source-drain} characteristics measurements performed through these quantum conductive latent ion tracks, it may be concluded, that true quantum wires have formed, possibly in form of SWCNTs or even elongated, light-ray straight poly-acetylene-reminiscent molecules of the cumulene form . . . ═C═C═C═C═C═C═ . . . and its mesomeric states.

### Outlook and Applications

The observed light sensitivity could lead to very small CCD-pixels as well as to super-efficient solar cells, a quantum wire's ballistic conduction's sensitive dependence on magnetic fields or electric fields could lead to ultra high density data storage (in form of quantum-mechanical field effect transistors) when combined with e.g. microscopically writable ferromagnetic or ferroelectric substrates. Also fast and practically loss-less power electronics applications such as magnetically or light triggered switches and transistors can be envisioned for the case that all billions of parallel quantum wires on a cm² chip are connected electrically parallel and perhaps even in (quantum-) phase. Another, conceptually very simple, but fabrication-wise difficult application would be the construction of a logical network from quantum interference rings see also [34] as similarly proposed for SQUIDS e.g. in [57]), perhaps even with inherently incorporated ADC—the pulse train behaviour shown in FIG. 19—inset demonstrates an instantaneous accurate digitizer just by counting the 2 mV-evenly spaced sharp current peaks along the voltage axis to be digitized—using the behaviour in FIG. 19—inset (FIG. 20) at the “input quantum wires”: Always two neighbouring quantum wires form a quantum interference ring if interconnected at both ends of their termination with a ballistic conductor (e.g a lead made of crystalline metal, or a carbon nanotube on the surface and a e.g. 2 DEG at the Si-DLC interface)—and the current through each one arm of such a ring is measured by a neighbouring such quantum wire interference-ring, and so on. A regular computer connected (via a tunnelling barrier) to the input- and output-side of the “chip” may simply generate and store basically a giant input-output look-up table of bit sequences or even decimals depending on how many quantum levels can be resolved. It could maybe be tuned a little by adding more ring-connections later, conceptually reminiscent of an FPGA and could ideally be able to process information instantaneously without heat losses.

### Appendix End

### DRAWINGS

FIG. 1: Experimental set-up for proving quantized conductivity in the nano wires (generated by latent particle tracks, caused by single swift heavy ions). The tip of a combined AFM/STM is line by line raster-scanned across the surface, and locally the current through the quantum wires at their terminals recorded—see also FIGS. 15—left and 15—right. For measuring the I_{sd}-U_{sd}—characteristics the scan is stopped on top of one QW's upper (hillock-shaped) termination and the drift at room temperature allows a stable measurement of the I-V-characteristics for about 10 seconds, before the electrically conducting probe tip has to be readjusted. Claimed here in this FIG. 1 is the protective resistor R_{protection} (8) between function generator (U_{sd}) and STM/AFM tip and the double resonant tunnelling set-up allowing measurements of quantum effects at room temperature, see also FIG. 21.

FIG. 2: Double bonded straight ideally conductive poly carbon molecule of the form . . . ═C═C═C═C═C═C═ . . . or of the mesomeric form . . . —C≡C—C≡C—C≡C—C≡C— . . . which (hypothesis) was generated by the passage of single swift heavy ions through an insulating DLC-layer because of the high energy density of the energy deposition. It is hereby emphasized that it is not a regular polyethene/polyacetylene molecule, as in the latter only every second C-C-bond is a (electrically conductive) double bond and additionally many H-atoms are attached on the latter molecules, which are practically not present in pure (electrically insulating) DLC.

FIG. 3: I_{sd}-U_{sd}-characteristics (“steps”) of single quantum wires at room temperature: The Fermi level of the (semi-) conducting tip scans (scanning of U_{sd}!) the quantum states of the quantum wire, the little steps in [1] in the U_{sd}-I_{sd}-characteristics, the large steps are supposedly the scanning states of a tiny grain at the end of the probe tip or the hillock-like ion track on the DLC-surface as a quantum dot (order 0.5 nm), which are necessary to make the thin needle-like peaks in I_{sd} in FIG. 5 visible at room temperature, where U_{sd} simultaneously shifts the quantum dot levels, i.e. represents the gate voltage U_{sg} for the quantum dot at the same time.

FIG. 4: Field-modulated I_{sd}-U_{sd}-characteristics of single quantum wires at room temperature—the enveloping curve is again the staircase characteristics and it is remarked, that the current modulation goes down all the way to zero nA (noise floor of order pA).

FIG. 5: Cut-out section of I_{sd}-U_{sd}-characteristics in the current suppression plateau near U_{sd}=0V at room temperature. Exactly vertical quantum conductance current peaks, here manifested by needle-like current peaks in the drain current I_{sd}; they occur with a “height” of up to 1 nA at U_{sd}<50 mV. (It is remarked, that the tunnelling contact resistances between the substrate and the quantum wire as well as between the AFM/STM probe tip and the quantum wire are still unknown/undetermined). These current peaks manifest electronically measurably the physics of the wave mechanical transmission of few electrons through the quantum wire's 1-dimensional quantum states.: Supposedly the upper most occupied quantum state of a quantum dot (sort of a HOMO of a conductive tiny grain at the probe tip or at the ion track's upper hillock-shaped termination on the DLC-surface) scans (by tuning U_{sd} up and down) the quantum states of the quantum wire finding the current peaks in a 2 mV separation.

FIG. 6: L_{d}-U_{sd}-characteristics without quantum wires, only the electrically conductive probe tip in contact with electrically conductive (B-doped) diamond layer, also at room temperature. This curve already shows Coulomb blockade, Coulomb suppression by mere charge quantization.

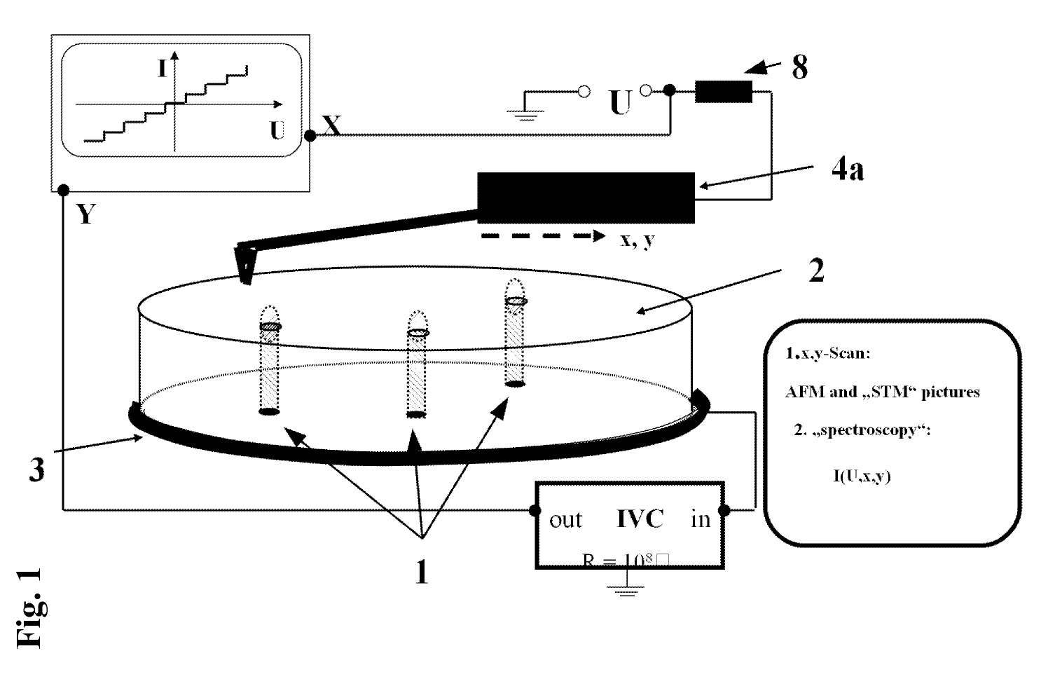

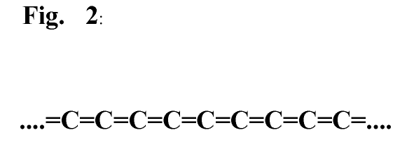

### Magnetic Field/E-Field Controlled/Gated QuantumFET:

FIG. 7: Embodiement 1: Power transistor—drawn are only 3 quantum wires, there is however at least 10¹⁰/cm² up to theoretically possible 10¹²/cm².

FIGS. 8, 9: Embodiement 2: Power transistor with “memory”

FIG. 10: Meander-shaped gate to control the power transistor with or without memory (i.e. with or without the ferromagnetic nanoparticles) via the inductance of that meander shaped lead, which can itself be formed also using the said array of quantum wires, but not necessarily, the concept can be using more conventional vertical and horizontal leads also. Only 1 dimension is shown—cross section view.

Embodiements 3a and 3b: analogous to as shown in FIGS. 7 and 8, 9, 10, 11: non-volatile and (re-) writable memory cell element, consisting only of one single or up to very few parallel connected quantum wires.

FIG. 11: Meander-shaped gate lead with an interconnect—via a protective resistor—to the outside at each “upper” turn-realized as in a Flash-Ram—to address each separately wired quantum wire memory cell via the inductance (or the electric charge) of each “lower” turn—otherwise as in FIG. 10. Only one dimension is shown—cross section view.

Embodiement 4: Optically modulated power transistor, photo detector, solar cell FIG. 12: Scheme

FIG. 13: I_{sd}-U_{sd}-characteristics “illuminated” and “dark” at room temperature.

FIG. 14: Embodiement 5: el.-magn. field-controllable/“gate-able” power transistor, photo detector, solar cell with drastically optimized sensitivity by introducing ideally conducting (R=0) layers as source drain electrodes, e.g. crystalline metals or superconductors at low temperatures, especially however 2-DEGs at room temperature at the hetero junction between the DLC-film and source drain electrodes. Model system for a 1-dimensional (1-directional) (pseudo-)superconductor at room temperature.

FIG. 15: Insulating DLC film—(100 nm thick) on an highly doped Si-wafer (from IWS Dresden, [49]) irradiated by M. Toulemonde at GANIL, CIRIL, Caen, France with single high-energy (4.1 MeV/nucleon) heavy ions. The protrusions in the AFM images FIG. 15—left (topography) clearly indicate the locations of the ion impact and the simultaneous current image FIG. 15—right) clearly demonstrates electrical conductivity through these tracks; about in the middle of the frame in FIG. 15—right the voltage (about 0.6V) polarity was reversed for better illustration purposes. The surrounding grey level corresponds to zero current.

FIG. 16: I-V curve with the tip resting on one of these track terminations on the DLC-film surface. On this wafer substrate piece from University of Göttingen [50] the latent track resistance was always relatively low (10 Mohms). The I-V curve is clearly light sensitive and especially shows non-zero current at zero voltage under illumination (inset). Quantized current levels were not clearly observed on these samples.

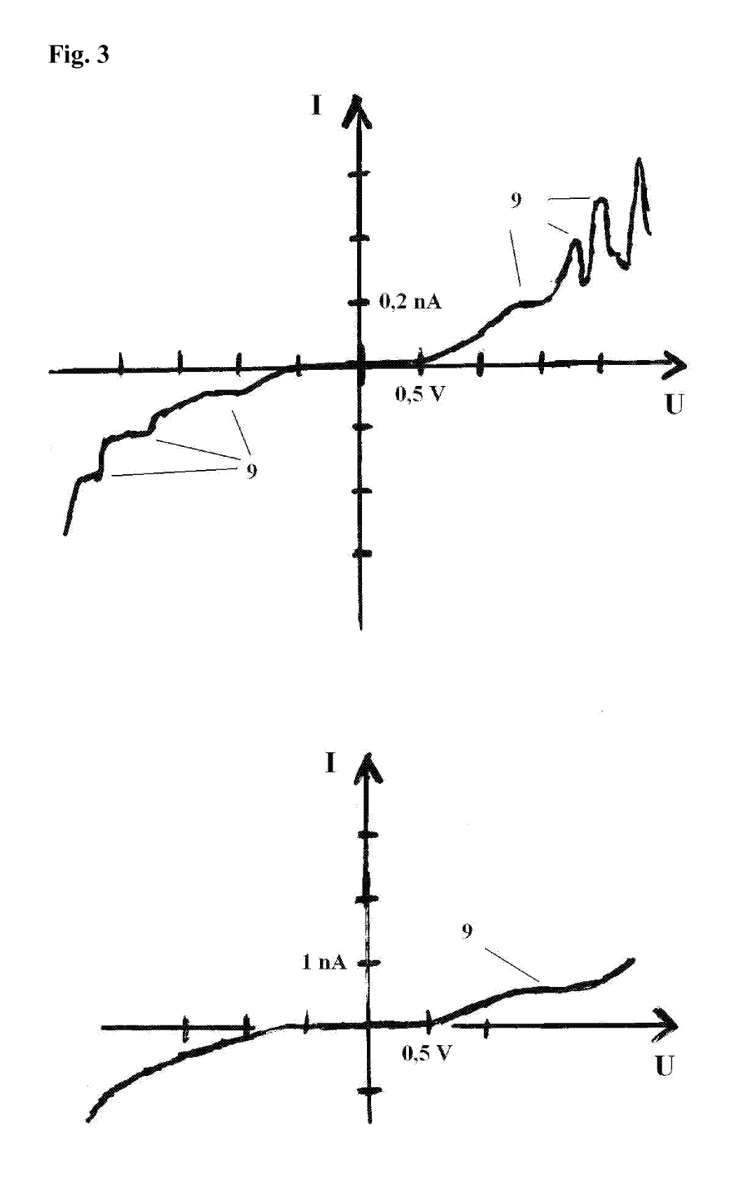

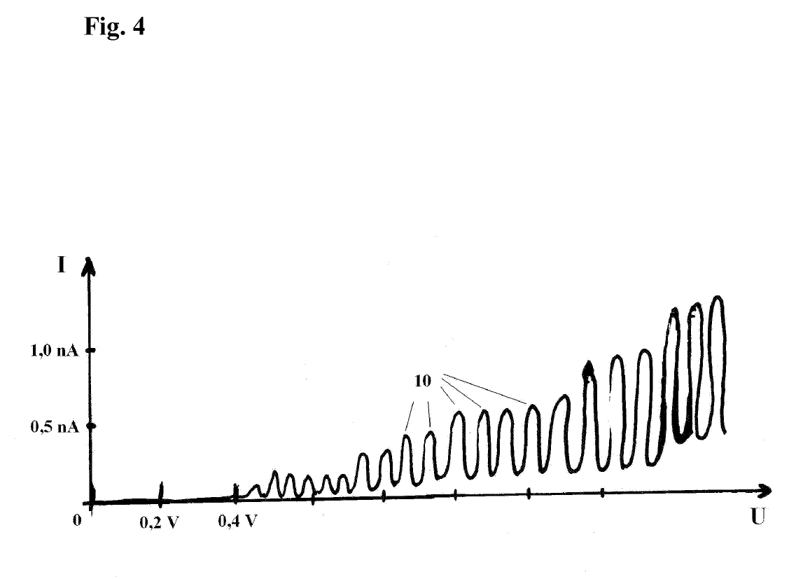

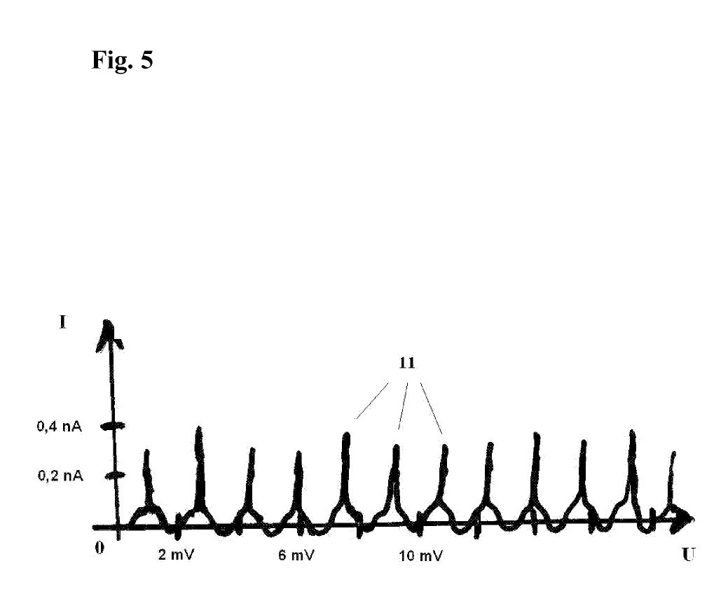

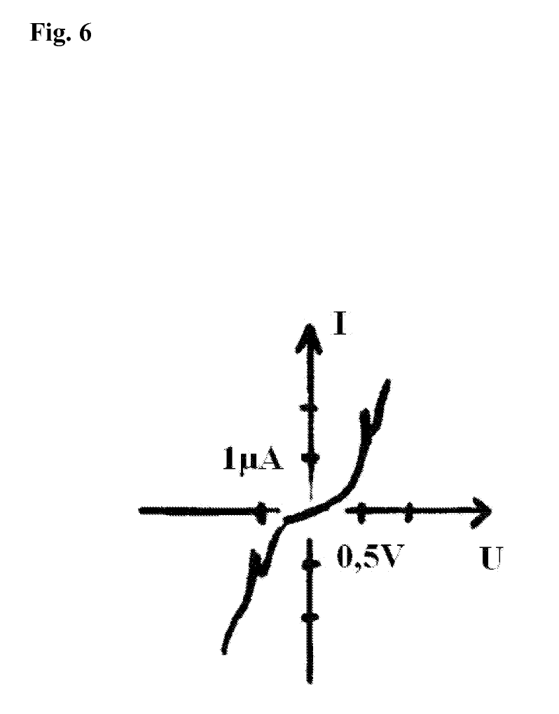

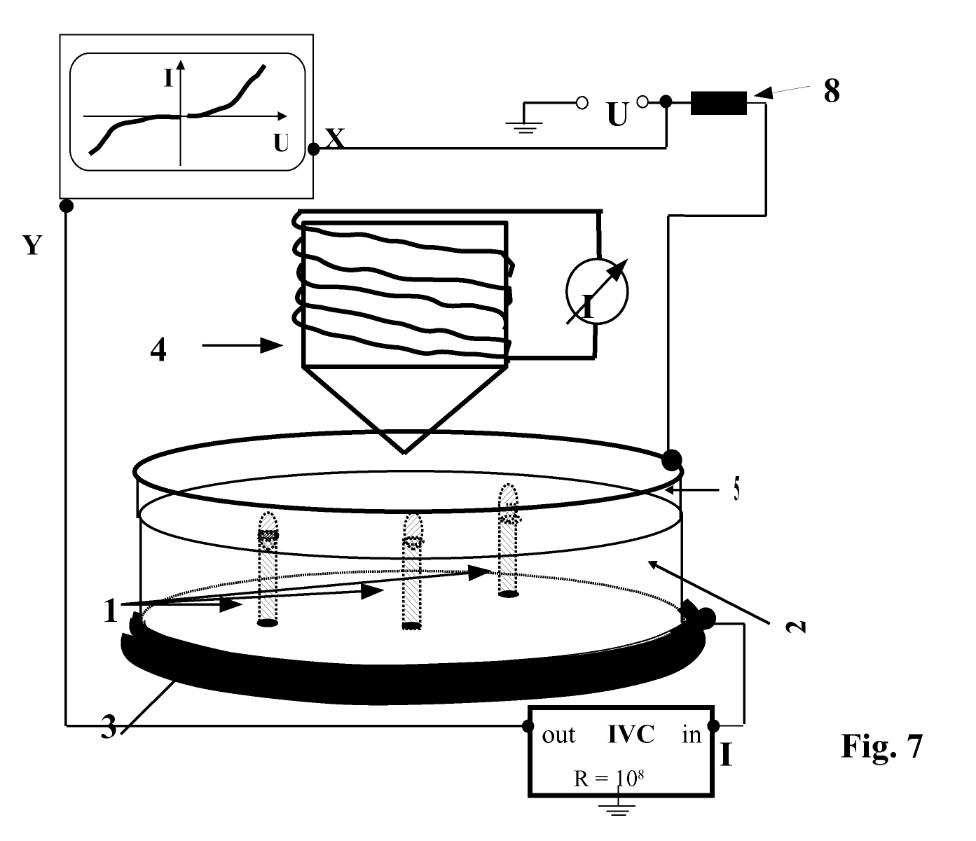

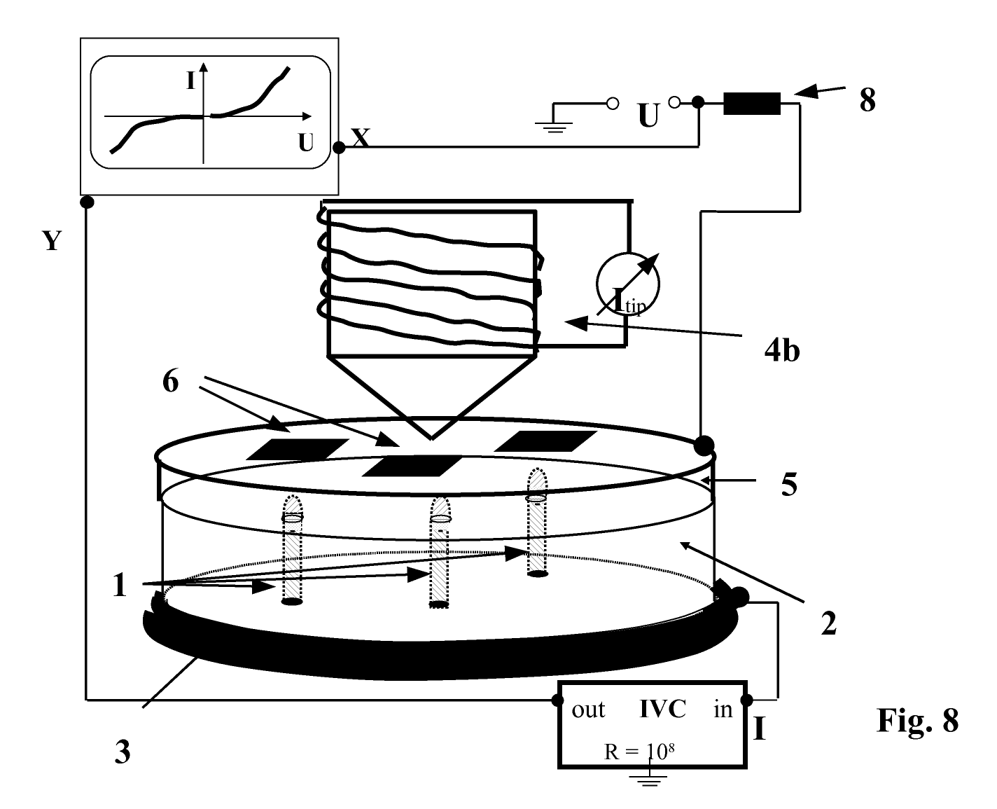

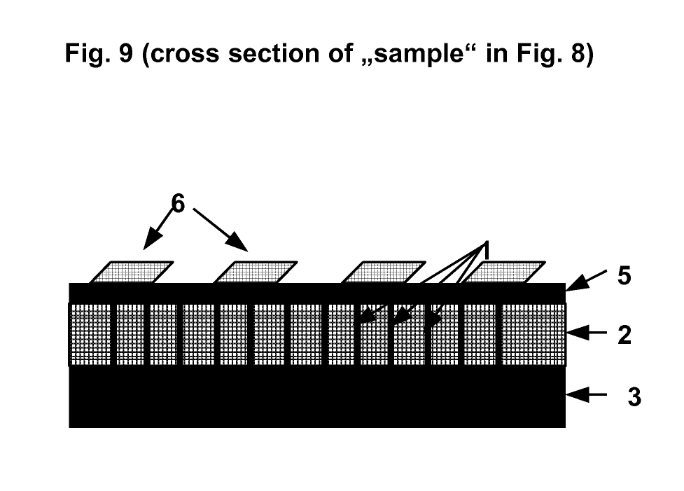

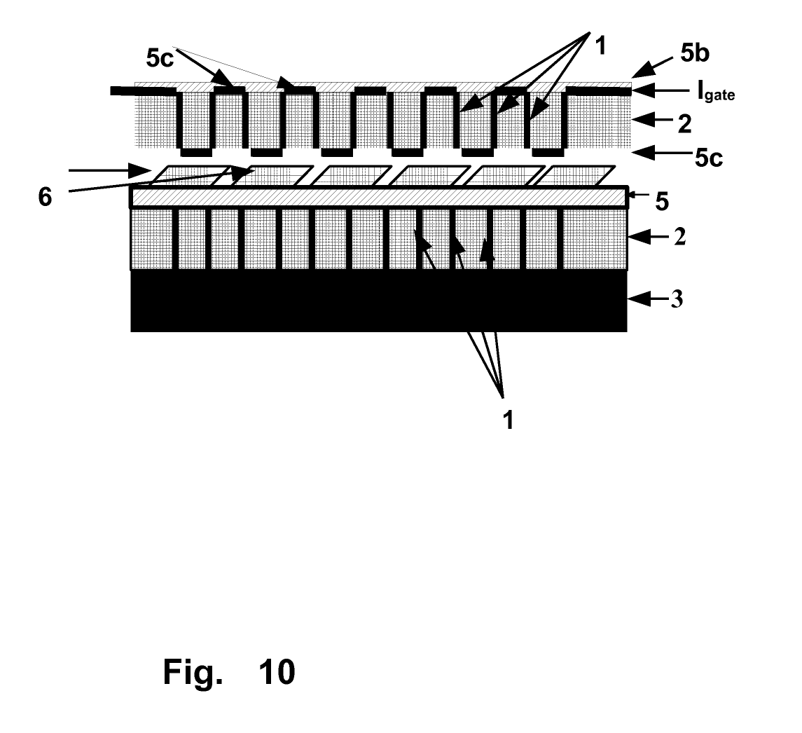

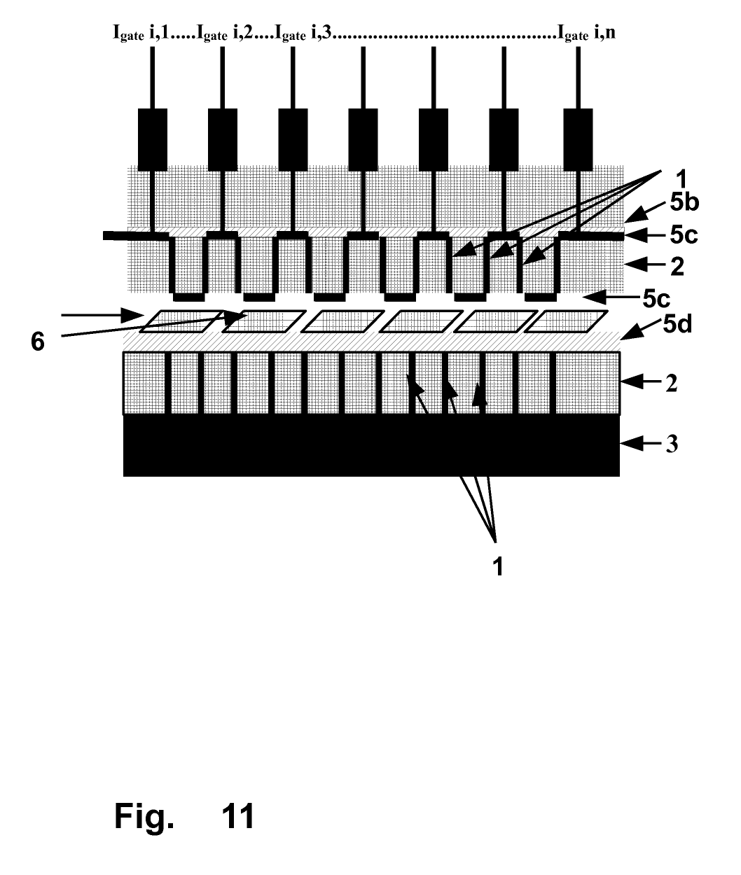

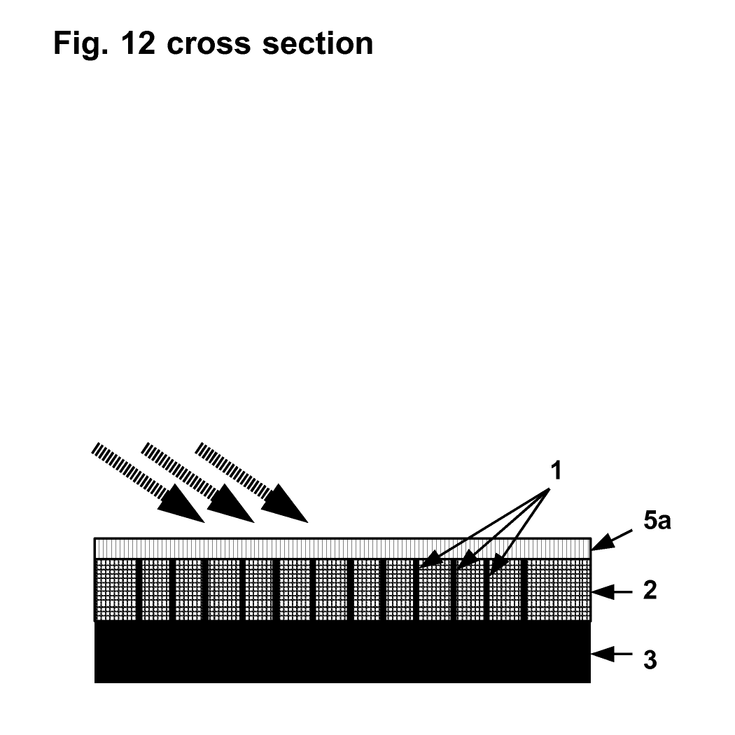

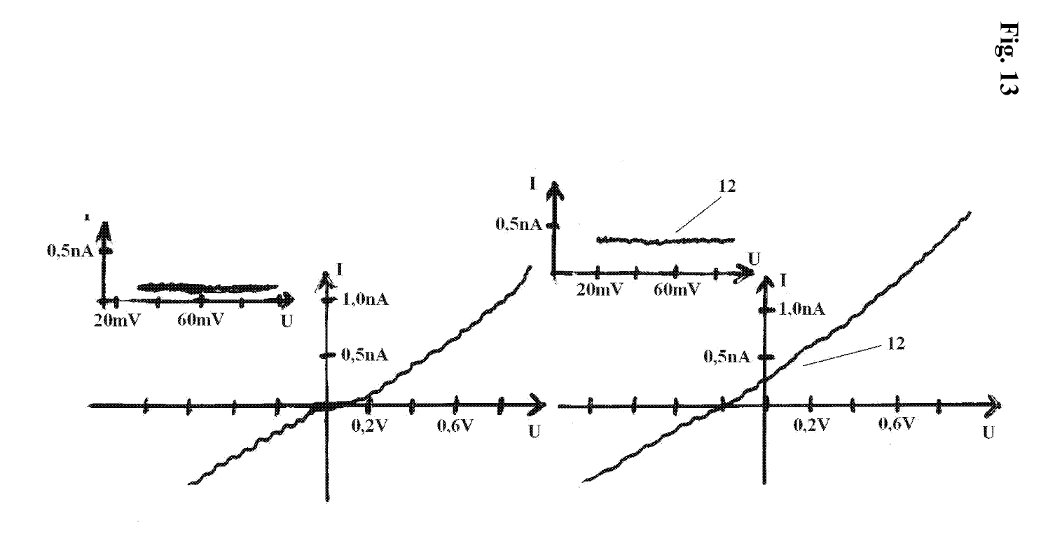

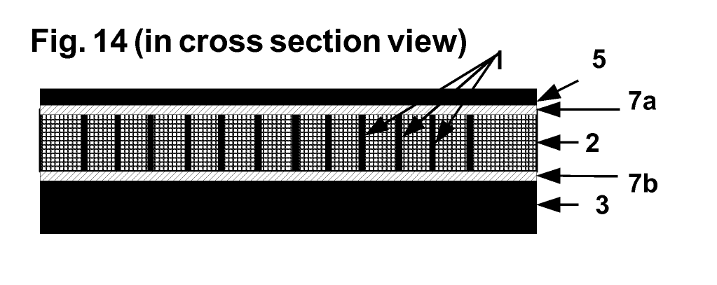

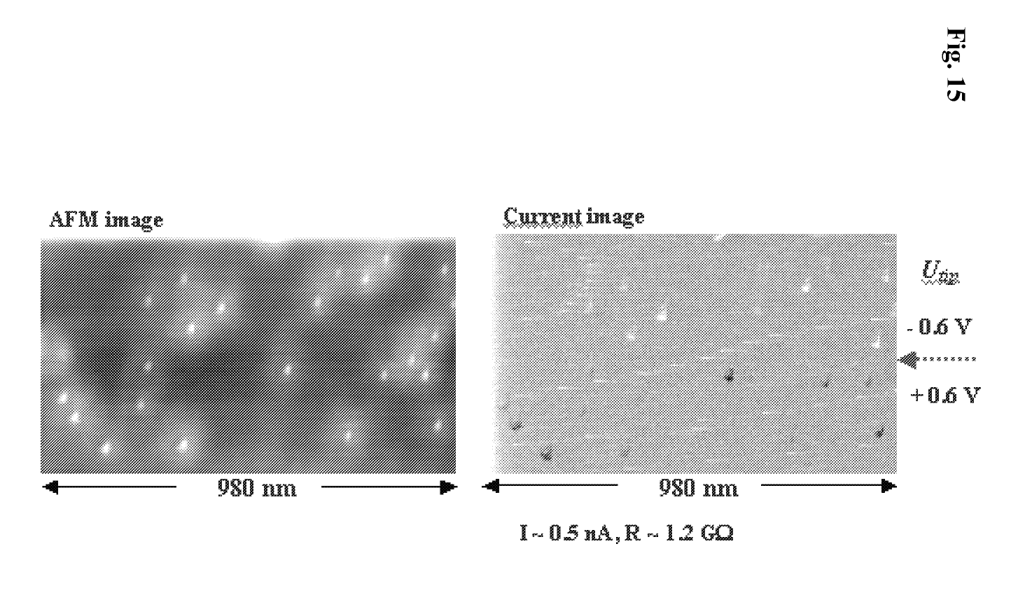

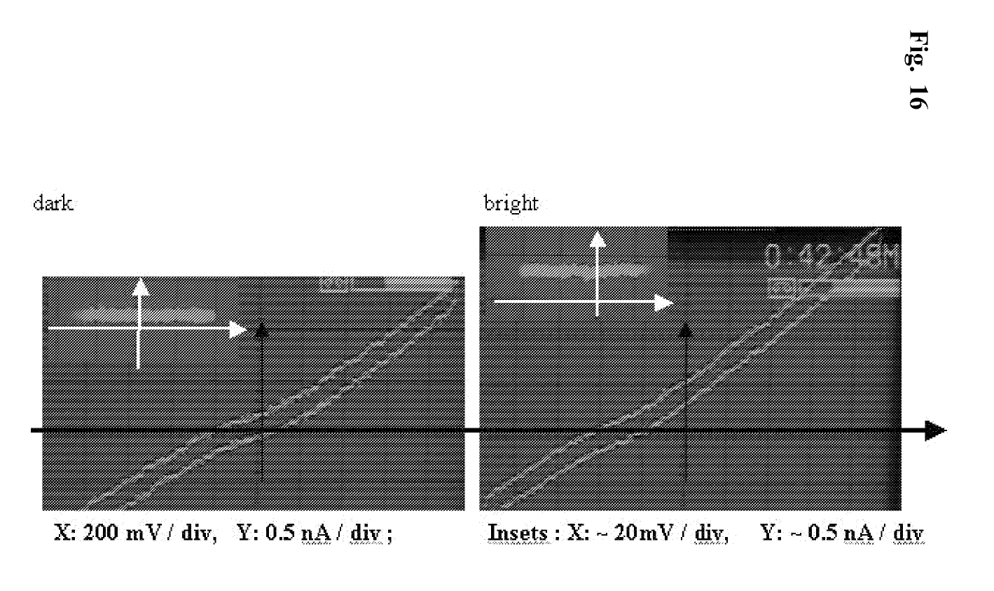

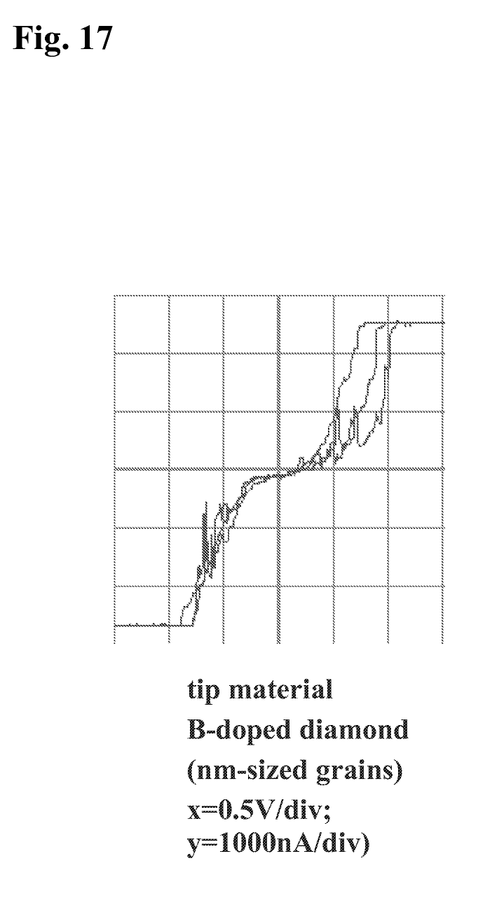

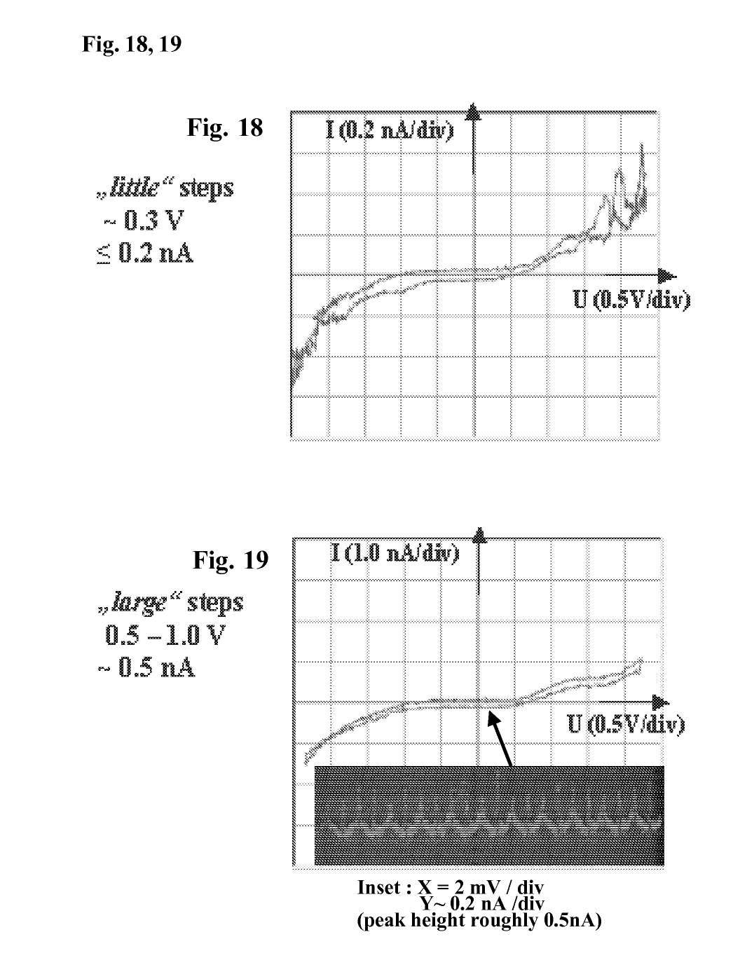

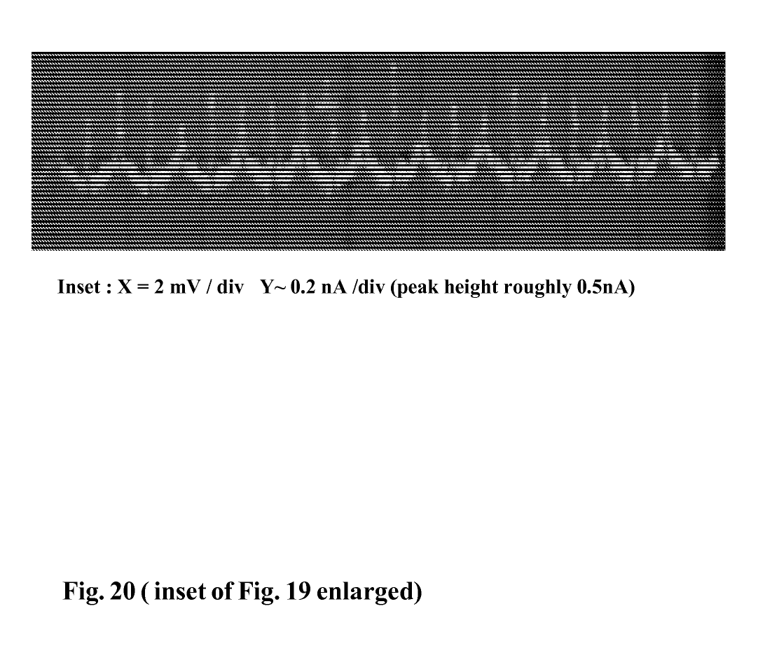

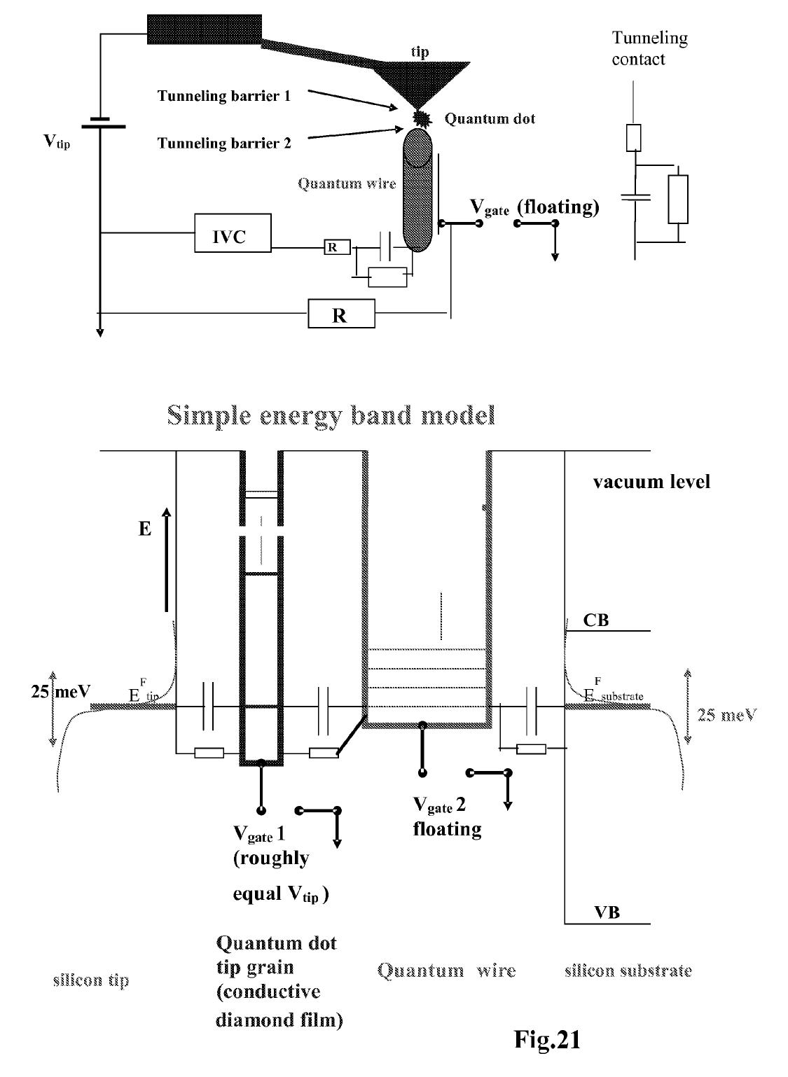

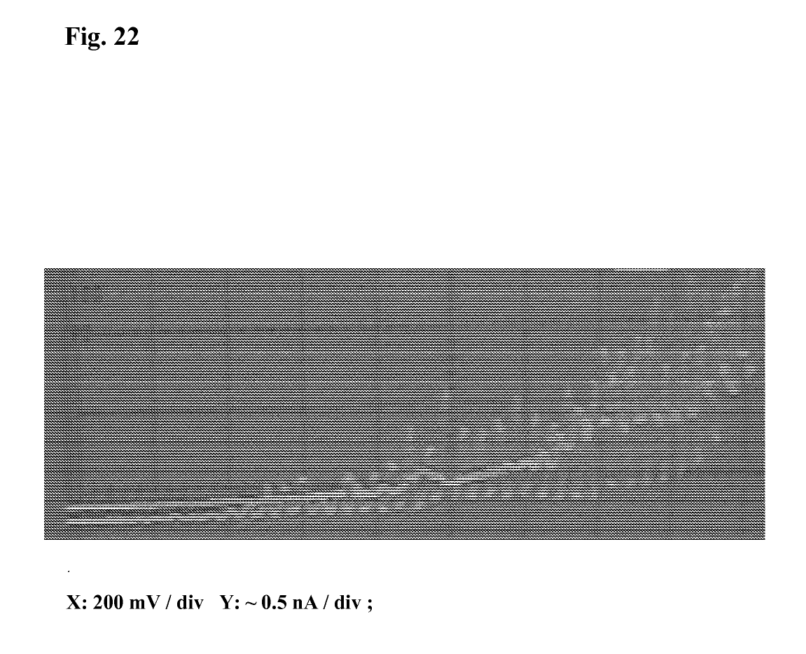

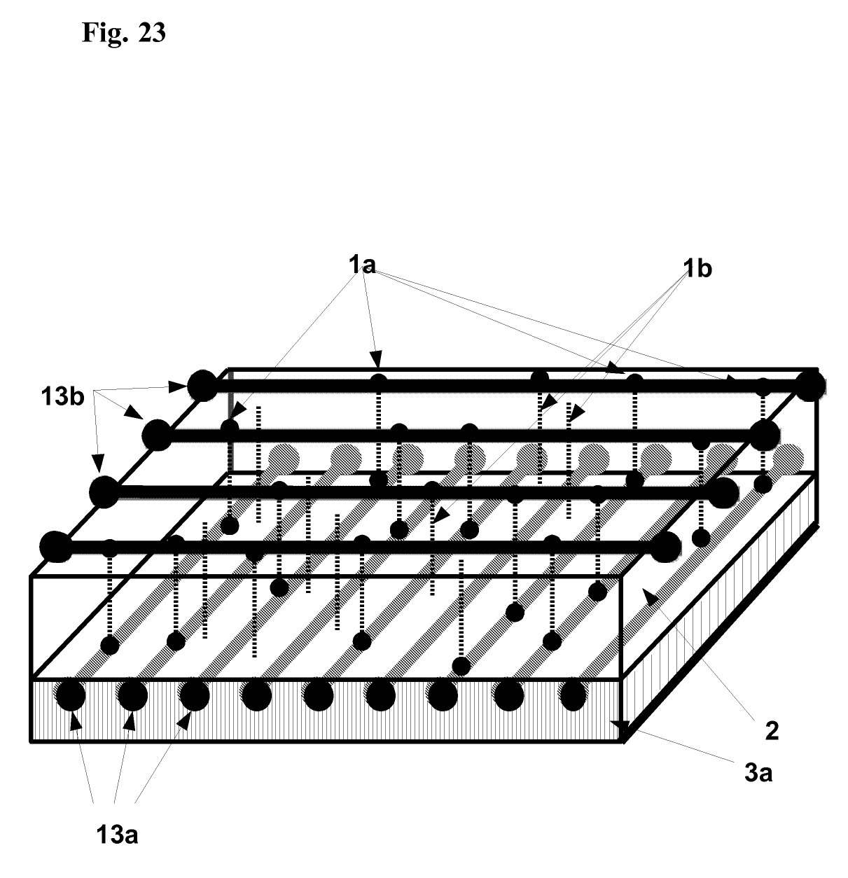

FIG. 17-20: I-V curves recorded with a cycle rate of several 10 Hz, roughly 50 Hz (not averaged) through ion tracks (substrate origin as in FIG. 15) at room temperature. (valid for all FIGS. 16-22: one complete I-V cycle, 2 oscilloscope traces, is shown due to “camera exposure time”): FIG. 17: “Normalizing” I-V curve with simply the same tip material as a “normalizing” sample, here no quantum wires at all—currents 3 orders in magnitude higher than on ion tracks and very unstable in magnitude. However, Coulomb suppression is already visible—just like FIG. 6. FIG. 18: typical I-V curves on an ion track, just like FIG. 3. FIG. 19: just as FIG. 18) with an inset showing sharp 2 mV spaced current peaks in the Coulomb suppression regime as sometimes observed very close around zero applied voltage—might represent density of states (DOS) of the conduction channels through a true 1-dimensional quantum wire—inset just like FIG. 5. FIG. 20: Inset of FIG. 19 merely displayed enlarged.

FIG. 21: Experimental situation for measuring at room temperature the sharp and evenly spaced conductance/current peaks in FIG. 19—inset and the therefore proposed energy band model for this double resonant tunnelling setup (quantum dot plus quantum wire): The energy states of the small grain quantum dot at the probe tip and/or the QW's upper hillock-shaped termination (e.g. a small asperity on the tip-end, here schematically drawn as an isolated grain/nanoparticle) scan (in energy) the energy levels of the true 1-dimensional quantum wire, which always has a floating gate here.

FIG. 22: Often spontaneously excited, an I-V curve with drastic oscillations was observed, which could be acoustically excited (even by weak “whisteling”), but did not alter the mean staircase shape. Cause is most likely the very sensitive modulation of the quantum mechanical current through the thus acoustically excited sample holder magnet resulting in oscillating B-fields and/or oscillating E-fields from the scanner piezo and/or phonons interacting with the QWs.

FIG. 23: A “crossed comb” structure of conducting leads is microfabricated into the atomically flat (insulating pure) Si- (or else) substrate—DLC-layer sandwich structure (one linear array of conducting leads below and a crossed one above the DLC-layer) and the crossings are chosen at a density slightly lower than the surface density of swift heavy ion hits, such that the statistically distributed conducting ion tracks (quantum wires) each interconnect one crossing on average. The densities can also be chosen such that on average several parallel ion track quantum wires will simultaneously interconnect on crossing of such conducting leads in the crossed “comb” structure.

### LEGEND OF THE NUMBERING IN THE FIGURES

1. Quantum wires generated by the through-passage of single high energy ions through an electrically insulating DLC-layer (2).
1a. Quantum wires generated by the through-passage of single high energy ions (1), which make electrical contact to a conducting lead on both sides of the DLC-layer (2).
1b. Quantum wires generated by the through-passage of single high energy ions (1), that do not make electrical contact to a conducting lead on both sides of the DLC-layer (2) (“missed hits”).
2. Electrically insulating matrix which is embedding the quantum wires and in which they were generated, e.g. DLC (resistivity 10¹² Ohms×cm), SiC, polymer, see [1], approximately atomically flat.
3. Electrically well conducting almost atomically flat substrate, e.g. highly doped Si-wafer.
3a. Electrically insulating almost atomically flat substrate (e.g. pure Si-wafer, or DLC-layer or else).
4a. AFM probe cantilever carrying an electrically well conducting probe tip (B-doped diamond).
4b. Magnetic tip of a size scalable with the desired component size/capability, which can also be strongly charged electrostatically.
5. Source-electrode layer, electrically well conducting material, e.g. metal film, at best crystalline (z.B. Au, Pt, Pa, Cu) or highly doped (e.g. with B, or P, N) semiconductor (Si-) material (e.g. Si, GaAs, highly doped—for instance with boron—diamond-like carbon, DLC).
5a. Source-electrode layer, transparent for the application of the optical transistor control/of the solar cell, e.g. extremely thin metal films, at best crystalline, or for instance ITO-glass (amorphous), or highly doped electrically conducting DLC, transparent for IR.
5b. Insulating support layer (e.g. SiO₂-foil, SiC-foil, polymer foil, DLC-foil etc., pure Si-wafer/foil etc.).
5c. (Preferably) ideally conducting electrical interconnect bridges (e.g. crystalline metal).
5d. Wiring matrix to address the single memory cells for read out, similar as in a Nand- or Nor Flash-Ram, e.g. as conceptually suggested in FIG. 23.
6. polarized/magnetized ferroelectric/ferromagnetic dipoles (“elementary magnets”), deposited as a thin film on the source electrode.
7. 7. (Preferably) bias-voltage-less 2-DEGs, proposed for the hetero junction between DLC-film and the source electrode (7a) and between DLC-layer and the drain electrode (7b), where a suitable highly doped semiconductor material for source and drain electrode has still to be found such that the 2-DEGs are formed on both sides of the DLC-layer.
8. protective resistor 100 Ohm-1 M Ohm respectively 1M Ohm-10 G Ohm.
9. Stair case source drain current I_{sd} versus source drain voltage U_{sd} curve, eventually with Esaki tunnelling
10. modulation of the I_{sd}-U_{sd}-stair case characteristics by a modulated gate field
11. quantum conductance peaks seen as sharp peaks in the current I_{sd}
12. light sensitive I_{sd}-U_{sd} characteristics
13. conducting leads microfabricated e.g. by local ion implantation or standard Si-processing on or into the atomically flat insulating substrate (3a—e.g. pure Si-wafer or a second DLC-layer below the “working DLC-layer” (2)).
(13b) conducting leads microfabricated on top of the DLC-layer (2) (the “working DLC-layer” containing the vertical quantum wires), perpendicular to the conducting leads underneath (13b) that “working DLC-layer” (2).

### ABBREVIATIONS

FM—atomic force microscope
CNT—carbon nano tube
DLC—diamond like carbon
DRAM—dynamic random access memory
FET—field effect transistor
GMR—giant magneto resistance
I-V curve—current voltage characteristic curve
I_{sd}—(source-) drain current
MWCNT—multi-walled carbon nano tube
QD—qunatum dot
QUID—quantum interference device
QW—quantum wire
SC—super conductor
SET—single electron transistor
SiC—silicon carbide
SQUID—superconducting quantum interference device
SWCNT—single walled carbon nano tube
U_{gate}—gate voltage versus arbitrary ground
U_{sd}—source-drain voltage
U_{source-gate}—voltage between source and gate
2-DEG—2 dimensional electron gas

### REFERENCES

[1] EP1096569A1, F. Ohnesorge et al
[2] F. Ohnesorge in “Record of the international Symposium on the electron and the electromagnetic field in Nanometer-scale structures” H. Nejo (Ed.), Springer 2000
[3] H. Akera, T. Ando, Phys. Rev. B, 11676 (1991)
[4] “Mesoscopic Physics and Electronics” T. Ando et al. (Eds.) Springer 1998
[5] G. M. Mikhailov et al. Nanotechnology 9, 1, (1998)
[6] zuriickgehend z. B. auf H. Weman et al., Phys. Rev. B 48(11), 8047 (1993)
[7] A. Gossard et al, Phys. Rev. Lett. 80(20), 4522 (1998)
[8] R. A. Jalabert et al., Phys. Rev. Lett. 68(23), 3468 (1992)
[9] EPO408966
[10] U.S. Pat. No. 6,566,704B2 Wun-bong Choi et al.
[11] B. H. Hong et al., Science 294, 348 (2001)
[12] z. B. “Leistungselektronik”, R. Felderhoff, Hanser ISBN 3446402616, 2006, oder z.B.: “Leistungshalbleiter-Handbuch. Mit Leistungs-MOSFETs”, J. C. van de Ven, ISBN: 3922705464
[13] M. H. Devoret et al. Ultramicroscopy 42-44, 22 (1992)
[14] B. Kramer, Physikalische Blatter 50(6), 543 (1994)
[15] S. J. Tans, A. R. M. Verschueren, C. Dekker, Nature 393, 49 (1998)
[16] C. Joachim, J. K. Gimzewski, A. Aviram, Nature 408, 541 (2000)
[17] H. W. Ch. Postma et al., Science 293, 76 (2001)
[17a] A. Bachtold et al., Science 294, 1318 (2001)
[18] DE102004003374A1 F. Keupl et al.
[19] B. Fischer, Rasterscan-Verfahren, GSI Darmstadt
[20] US5835477, G. Binnig, H. Rohrer, P. Vettiger “Mass-storage applications of local probe arrays”
[21] DE10036897C1 J. Kretz et al.
[22] J. Appenzeller et al. PRL92(22), 226802 (2004).
[23] The not pursued and not published patent application at the DMPA file#10019040.5 (Frank Ohnesorge “Room temp. superconductor, application as power transistor”) of 18.04.2000 already incorporates the core statements of realizing a power transistor by means of an array of many electrically parallely connected true quantum wires and the right of originality is claimed at this date. The same holds for DMPA file#10019039.1 (Frank Ohnesorge, “Artificial retina”) of 18.04.2000.
[24] “Single-electron devices and their applications”, Konstantin K. Likharev, Proceedings of the IEEE, 87(4), pp. 606-632 (1999).
[25] e.g. “Mesoscopic Physics and Electronics” eds. T. Ando, Y. Arakawa, K. Furuya, S. Komiyama, H. Nakashima, Nanoscience and Technology Series, Springer 1998.
[26] M. H. Devoret, D. Esteve, C. Urbina, Nature 360, 547 (1992).
[27] O. M. Auslaender, A. Yacoby, et al., Science 295, 825 (2002).
[28] Reed M. A., C. Zhou, C. J. Mueller, T. P. Burgin, J. M. Tour, Science 278, 252-254 (1997); C. Kergueris, J.-P. Bourgoin, et al., PRB 59, 12505 (1991); H. Nejo, Nature 344, 641 (1990) and Nature 353, 640 (1991); H. Nejo, J. Vac. Sci. Technol. A8(1), 275 (1990); [29] P. G. Collins, A. Zettl, H. Bando, A. Thess, R. E. Smalley, Science 278, 100 (1997);
[30] C. Joachim, J. K. Gimzewski, Chem. Phys. Lett. 265, 353-357 (1997).
[31] B. H. Hong, S. C. Bae, C.-W. Lee, S. Jeong, K. S. Kim, Science 294, 348 (2001).
[32] X. D. Cui, A. Primak, et al., Science 294, 571 (2001).
[33] Partly in: “Record of the “Int. Sympos. on the Electron and Electromagn. Field in Nanometer-Scale Structures”, in Springer, ISBN 3-540-67244-3, ed. H. Nejo (2000);
[34] F. M. Ohnesorge, M. Toulemonde, T. Wittke et al, EPA 99121606.0, 27./29.10.99
[35] R. Spohr, New Astronomy Rev. 42, 189 (1998), and Springer 1997;
[36] R. L. Fleischer, P. B. Price, R. M. Walker, Nuclear Tracks in Solids, University of California Press, Calif., USA 1975.
[37] K. Schwartz, C. Trautmann, T. Steckenreiter, O. Geiss, M. Kraemer, PRB 58, 11232-11240 (1998).
[38] A. Wolf, S. Ziwy, Y. Korchev, N. Reber, R. Spohr, Cell. Mol. Biol. Lett. 4(4), 553-565 (1999).
[39] M. Toimil-Molares, V. Bushmann, D. Dobrev, R. Neumann, R. Scholz, I. Schuchert, J. Vetter, Adv. Materials 13 (1), 62-65 (2001); D. Dobrev, J. Vetter, N. Angert, R. Neumann, Electrochim. Acta 45(9), 3117-3125 (2000).
[40] B. Fischer, J. Barak, E. Adler, S. Metzger, NIM B 146, 587-595 (1998).
[41] M. Toulemonde, Ch. Dufour, A. Meftah, E. Paumier, NIM B 166-167, 903-912 (2000); F. Pawlak, Ch. Dufour, et al. NIM B 151, 140-145 (1999).
[42] H. Hofsäβ, private communication.
[43] F. M. Ohnesorge, R. Neumann, Europhysics Lett. 50(6), 742-748 (2000).
[44] F. M. Ohnesorge, A. Müller, R. Neumann, Nucl. NIM B 166-167, 938-943 (2000).
[45] F. M. Ohnesorge, unpublished results, to be published.
[46] D. Fink, R. Klett, Brazilian J. of Physics 25, 54-75 (1995).
[47] M. Waiblinger, C. Sommerhalter, et al, Appl. Phys. A, 69, 239 (1999).
[48] R. Neumann, NIM B 151, 42 (1999); A. Müller, C. Müller, R. Neumann, F. Ohnesorge, NIM B 166-167, 581-585 (2000).
[49] J. Berthold, C. F. Meyer, T. Schuelke, B. Schultrich, T. Witke, Surface and coatings technology 116-119, 609-613 (1999).
[50] H. Hofsaess, H. Binder, T. Klumpp, E. Recknagel, Diam. Relat. Materials 3, 137 (1994); H. Hofsaess, C. Ronning in Proc. 2^{nd} in conf. on beam proc. of adv. mat.” eds. J. Singh, S. M. Copley, J. Mazumder, p. 29-56, ASM Int. Materials Park, 1996.
[51] Boron doped PVD/CVD-diamond coated Si-tips, Nanosensors, Wetzlar, FRG.
[52] J. Vetter, G. H. Michler, J. Naumann, Rad. Eff. and Def. in solids 143, 273-286 (1998).
[53] B. Fischer, private communication.
[54] K. v. Klitzing, private communication.
[55] A. Gossard et al., PRL 80 (20), 4522 (1998)
[56] H. Ness, S. A. Shevlin, A. J. Fisher, PRB 63, 125422 (2001).
[57] Buckel, Supraleitung, Wiley Verlag.
[58] DE102009031481A1, DE102010007676.7, GB1011618.4.

1. Electronic component, in particular a diode, a switch, a transistor, a quantum field effect transistor, a power diode, a power transistor, a photo diode, a solar cell, a digitizer,
comprising at least one quantum wire of a 2-dimensional array of parallel vertical quantum wires,
characterized in that that
the quantum wire is a elongated carbon chain comprising carbon double bonds or graphitization,
wherein the quantum wire has a stepped staircase non-linear I-V-characteristics (9).

2. Electronic component according to major claim 1,
wherein the quantum wire is substantially light ray straight,
wherein the quantum wire has substantially sharp current peaks in this said stepped staircase non-linear I-V-curve in particular within the Coulomb suppression plateau, representing a 1-dimensional quantum mechanical electronic transmission current through distinct quantum levels of the quantum wire.

3. Electronic component according to claim 1,
wherein the I-V-curve is sensitive to external quasi-static electric, magnetic and electroacoustic fields (10) and to electromagnetic irradiation fields (12).

4. Electronic component according to major claims 2 and 3,
characterized in that
that it is in particular a diode or power diode comprising an array of quantum wires,
where a 2-dimensional array of 10⁶-10¹⁵, in particular 10⁹-10¹², vertical geometrically parallel true quantum wires per cm² are connected electrically parallel interconnecting source and drain contacts of said quantum wire field effect transistor,
where the quantum wires can be tilted up to 90 degrees, in particular up to 45 degrees, also in groups,
where the true quantum wires, in particular, are light ray straight,
where the true quantum wires are fabricated by light ray straight passage of from several 100 keV to 100 MeV/n swift light to heavy ions of a positive charge state of in particular 1⁺ up to 60⁺ or negative through an electrically insulating layer of DLC or SiC or polymer,
where these true quantum wires are SWCNTs or graphitized carbon chains in particular of the cumulene form . . . ═C═C═C═C═C═C═ . . . or of the mesomeric polyacetylene-reminiscent form . . . —C≡C—C≡C—C≡C— . . . ,
where alternatively a 2-dimensional crystal of vertical upright standing elongated conductive molecule chains and/or also mixed with insulating molecule chains is fabricated by Langmuir-Blodgett and Langmuir-Schäfer technique reaching an area density of up to 10¹⁵/cm², where these light ray straight true quantum wires connected in parallel exhibit real 1-dimensional ideal conductivity in form of a 1-dimensional quantum mechanical electronic transmission current,
wherein these true quantum wires exhibit also at room temperature a stair case with in particular up to 16 steps I-V curve (9) source-drain current I_{sd} versus source-drain voltage U_{sd} along the quantum wire—and not just as a function of a gate voltage U_{gate}—by means of which the current can be switched in steps,
further that these true quantum wires exhibit quantum conductance/current peaks (11), which are in particular extremely sharp peaks in the current I_{sd} in this I_{sd} versus U_{sd} characteristics along the true quantum wire—and not just as a function of a gate voltage U_{gate}—within the I-V curve's plateaus, especially the Coulomb blockade current suppression plateau around 0 Volts +/−50 mV, which here is additionally suppressed by conductance quantization effects, where these quantum conductance peaks are visible at room temperature due to a double resonant tunneling structure constructed here for measurement of the I-V curve.

5. Electronic component in form of a switch, a transistor, power transistor, photodiode, according to claims 1-3 characterized in that
that it comprises at least one of these true quantum wires or the said 2-dimensional array thereof respectively which exhibit I-V curves characterized by the fact that these I_{sd} versus U_{sd} curves can be sensitively modulated by applied external controlling gate fields—magnetic or electric or electro-acoustic according to the field modulated staircase I-V curve (10) and optical according to the light sensitive I-V curve (12),
that the presently invented power transistor consists of many parallel true quantum wires, in particular 10⁹-10¹²/cm²—that are identical such that the I-V characteristics of the single true quantum wires hold qualitatively also for the entity of the electrically parallel connected quantum wires, where source and drain electrode (3,5) are ideal electric conductors as well, such as 2-DEGs at room temperature (7a,7b) or superconductors at low temperatures or thin crystalline metal or semiconductor at room temperature or moderately lowered temperatures, that the presently invented power transistor's transistor characteristics can be tailored by adjusting the strength and inhomogenuity of the gate field,
where differently strong and differently directed gate fields act locally on the different single quantum wires or groups thereof, by means of which every single quantum wire or every group of quantum wires obtains a different I-V-curve resulting in a tailored mean total I-V curve I_{sd total} versus U_{sd total} of the power transistor.

6. Power transistor according to patent claim 4 characterized in that the source drain current and its I-V characteristics in the quantum wires and in the quantum wire array in this operational mode is controlled by an externally applied magnetic field, where by means of a variable current in an inductance surrounding an soft-magnetic iron core (4b), spatially closely above the quantum wire array and by means of its separation from the quantum wire array the magnetic field in the quantum wire array is controlled, where by means of a variable current strength I_{gate} through a meander shaped circuitry (formed by (1) and (5c) in FIG. 3b-I) enveloping/around/above the single quantum wire terminations the controlling magnetic gate field is adjusted by said I_{gate}, driven through the meander-shaped conductive lead formed by the quantum wires (1) or here also conventional nanowires and the interconnecting bridges (5c),
where the current I_{sd} through the quantum wires and I_{sd total} through the power transistor can be controlled in steps,
where in both above cases an external inhomogeneous but spatially and in terms of strength defined magnetic field is generated across the quantum wire array, which thus exhibits a adjustable inhomogenuity that can be changed over time and thus allows tailoring of the total I-V curve of the presently invented power transistor.

7. Power transistor according to patent claim 6, characterized in that
the source drain current and its I-V characteristic in the quantum wires and the quantum wire array is controlled or switched by an externally applied magnetic field by means of depositing and suitably magnetizing a ferromagnetic layer (6) on top of the quantum wire array by writing on with a magnetic tip (4b) mounted to a scanning force microscope or with said meander structured circuitry of claim 5 formed by (1) and (5c),
where the ferromagnetic layer (6) consists of Fe or Co or Ni or Sm or Nd or a layer of ferromagnetic nanoparticles of Fe or Co or Ni or Sm or Nd,
where a non-volatile memory effect of the transistor working point and the source drain I_{sd}-U_{sd} characteristics is achieved,
further characterized in that the transistor's source drain I-V characteristics can be tailored by microstructurally magnetizing the ferromagnetic gate field generating layer, by means of which a defined inhomogenuity of the gate field across the quantum wire array is achieved.

8. Power transistor according to patent claim 7, characterized in that
that the source drain current and its I-V characteristics can be controlled or switched by an externally applied electric field by means of a electrically charged scanning probe tip, analogous to claim 5,
where by means of depositing or embedding into the quantum wire array and suitably polarizing of a ferroelectric or antiferroelectric layer or by applying a lateral voltage within that polarizable layer, the transistor working point and the source drain I_{sd}-U_{sd} characteristics can be tailored with non-volatile memory effect, analogous to claim 6,
where the source drain I-V characteristics can be tailored by microstructural polarizing of the ferrorelectric or antiferroelectric gate field generating layer, whereby a defined inhomogenuity of the gate field across the quantum wire array is generated,
where the ferroelectric layer consists of a liquid crystal layer of polar molecules or a layer of polar nanoparticles, where the meander-shaped circuitry formed by (1) and (5c) can also be used to supply an electric field.

9. Electric component according to claim 3, characterized in that that it is in particular a power transistor or power switch or power photodiode,
wherein the source drain current and its I-V curve in the quantum wires and the quantum wire array is modulated or controlled or switched by external irradiation of electromagnetic radiation such as infrared or visible or ultra-violett or x-ray onto the 2-dimensional quantum wire array, where the quantum wire array then acts as a photodetector according to the light sensitive I-V curve (12) of a single quantum wire
where by means of a quasi constant but time-variable inhomogenuity of the light intensity distribution across the quantum wire array the I-V characteristics of this optically gated transistor can be tailored,
where by locally obscuring parts of the 2-dimensional quantum wire array for the said irradiation, the I-V characteristics of this optically gated transistor can be tailored.

10. Electronic component according to claim 9 which is in particular a power quantum wire array solar cell characterized in that functional feature
that under exposing to light at 0V source drain voltage a non-zero source drain current (12) is detected and light energy is converted into electrical energy, where the source electrode consists of transparent electrically ideally conductive material,
where this said material is indium tin oxide or a few nm to a few 10 nm thin electrically conductive metal or semiconductor layer which are ideally forming also a 2-DEG (7a,7b) with the diamond like carbon film.

11. Electronic component according to any of the claims 3, 9, 10,
characterized in that that it is in particular a light pixel sensor array comprising electrically connected quantum wires according to the functional feature light sensitivity of the quantum wires' I_{sd}-U_{sd} curve according to patent claim 3, 9, 10,
where this operational mode is characterized in that
the single quantum wires are contacted each separately and the light effect on the single source drain currents in the single quantum wires of that 10⁹-10¹²/cm² quantum wire array is read out position dependent,
where the separate contacting of the single quantum wires should be realized as in a charge coupled device or a Flash-RAM,
where a horizontally crossed comb structure of nanometric wires (13a and 13b) is prepared on the upper and lower sides of DLC-layer (2) and the surface density of swift heavy ion hits is adjusted just above the area density of the wire crossings such that on average every connecting wire crossing is interconnected by one ion track quantum wire (1a) or where the surface density of swift heavy ion hits is adjusted well above the area density of the wire crossings such that on average each connecting wire crossing is interconnected by several parallel ion track quantum wires,
where the light sensitivity of the quantum wire photo transistors can be tuned via the external fields generated by the meander shaped circuitry formed by (1) and (5c).

12. Electronic component according to any of the claims 1, 2, 3, 6, 7, 8, 9, 10, characterized in that that it is in particular a power diode, power switch, power transistor or solar cell,
characterized in that source and drain electrodes consist of an ideally conducting layer where this said layer consists of crystalline metals at room temperature or moderately lowered liquid N₂ temperatures or consists of superconductors at low temperatures or consists of a 2DEG (7a,7b) at room temperature,
where by quantum mechanical phase shift effects of the electronic wave functions in the quantum wires the sensitivity and efficiency of the transistor gain and the solar cell yield is enhanced,
which also represents a model system for a 1-dimensional—direction parallel to the quantum wires—pseudo superconductor at room temperature or slightly lowered temperatures in form of a quantum interference device collectively coupling billions of quantum wires.

13. Electronic component according to at least one of the claims 1-3,
characterized in that that it is a quantum field effect transistor according to the functional feature true quantum wire with quantum conductance/current peaks, wherein in this operational mode
the source drain current only through one or simultaneously through a few—1 to 100—geometrically and electrically parallel connected true quantum wires is separately detected at room temperature or moderately lowered temperatures,
where the true quantum wire is a voltage digitizer,
where the quantum field effect transistor is a quantum mechanical memory cell and can be switched in current steps I_{sd},
where the source drain current through the said true quantum wires or the few parallel connected quantum wires carries the secondary stored information of at least 1 to 16 bits,
where an external magnetic or electric or electro-acoustic field or radiation field gates the quantum field effect transistor and controls or modulates the current I_{sd} through the said true quantum wires also in several steps,
where in immediate vicinity of the source and or drain terminations of the quantum wires a ferromagnetic and or ferroelectric and or antiferroelectric layer (6) is deposited, which primarily carries the stored information by means of that the in a non-volatile manner stored local field controls or modulates in steps the current I_{sd} through the one or few quantum wires directly underneath,
where this ferromagnetic or ferroelectric or antiferroelectric layer (6) is locally magnetized or polarized by a magnetic or electrically charged probe tip (4b) of a scanning probe microscope, where the meander structure of claims 5 and 6 broken up into single wire loop inductances formed by (1) and (5c) can be used to write onto the single quantum wire or quantum wire group transistors by either controlling the quantum wires conductance directly or via magnetizing the ferromagnetic nanoparticles deposited above the quantum wire terminations, where the same can be realized equivalently with ferroelectric/antiferroelectric nanoparticles where the wire loops would charge them electrically,
where this ferromagnetic layer consists of Fe or Co or Ni or Sm or Nd or nanoparticles of such materials,
where this ferroelectric or antiferroelectric layer consists of polarizable nanoparticles,
where the source drain currents I_{sd} through the single true quantum wires or small quantum wire groups can be read out separately either by a circuitry as in a Nand- or NOR Flash-RAM or by means of one or many scanning probe tips stationary or mounted to a rotating HDD-read-write head,
where a horizontally crossed comb structure of nanometric wires (13a and 13b) is prepared on the upper and lower sides of DLC-layer (2) and the surface density of swift heavy ion hits is adjusted just above the area density of the wire crossings such that on average every connecting wire crossing is interconnected by one ion track quantum wire (1a) or where the surface density of swift heavy ion hits is adjusted well above the area density of the wire crossings such that on average each connecting wire crossing is interconnected by several parallel such ion track quantum wires (1a) making contact to a conducting lead on either of the two comb structures.

14. Method for measuring at room temperature an electronic component according to claims 1-3, in particular in form of a specialized measurement set-up for characterizing and examining of true quantum wires and their source drain current I_{sd} versus source drain voltage U_{sd} characteristics and for fabricating prototype devices of the above proposed is characterized in that
it consists of a combined scanning tunneling and scanning force microscope,
where an electrically conductive probe tip at the end of a cantilever spring connected to a voltage source U_{sd} is initially raster-scanned across the 2-dimensional vertical quantum wires' array initially for detecting the single quantum wires' terminations, after which the raster-scan is stopped with the tip positioned on top of one quantum wire termination and then the I_{sd}-U_{sd} curve of this quantum wire is measured across a protective resistor (8),
where the protective resistor is at least 25.8 kΩ,
where the probe tip carrying a quantum dot is with adjustable load in mechanical or weak tunneling contact with the upper termination of the quantum wire defined as source contact,
where the one or both quantum wire terminations carry a quantum dot,
where double resonant tunneling occurs between the quantum dots on one or both quantum wire terminations and the quantum wire itself enabling room temperature measurements of I-V curves on the mV scale identifying very sharp and only mV-spaced energy levels in the quantum wires directly in form of the quantum conductance current peaks (11) in the I-V-curves (I_{sd} versus U_{sd}),
where by double resonant tunneling through the sharp quantum levels in the quantum dots the thermal noise of 25 meV gets filtered out and the sharp quantum levels of the quantum wires themselves become visible in the I_{sd}-U_{sd} curve in form of sharp current peaks within the current plateaus, even within the zero current—Coulomb suppression—plateau,
where the lower terminations of the quantum wires which comprises the entity of drain contacts are connected to earth ground via a further protective resistor and an I-V converter,
where the protective resistor is at least 6.45 MQ.
